(19) United States
(12) Patent Application Publication
(10) Pub. No.: US 2018/0107118 A1
(43) Pub. Date: Apr. 19, 2018

(54) PATTERN FORMING METHOD, METHOD FOR MANUFACTURING ELECTRONIC DEVICE, AND ACTINIC RAY-SENSITIVE OR RADIATION-SENSITIVE RESIN COMPOSITION

(71) Applicant: FUJIFILM Corporation, Tokyo (JP)

(72) Inventors: Akiyoshi GOTO, Shizuoka (JP); Keita KATO, Shizuoka (JP)

(73) Assignee: FUJIFILM Corporation, Tokyo (JP)

(21) Appl. No.: 15/791,372

(22) Filed: Oct. 23, 2017

Related U.S. Application Data
(63) Continuation of application No. PCT/JP2016/060983, filed on Apr. 4, 2016.

(30) Foreign Application Priority Data
May 14, 2015 (JP) 2015-098850

(51) Int. Cl. G03F 7/20; G03F 7/16; C08J 3/28; G03F 7/038; G03F 7/039; G03F 7/32

(52) U.S. Cl. CPC G03F 7/2004; G03F 7/16; G03F 7/325; G03F 7/038; G03F 7/0397; C08J 3/28

(57) ABSTRACT

A pattern forming method includes at least (i) forming a film on a substrate, using an actinic ray-sensitive or radiation-sensitive resin composition, (ii) irradiating the film with actinic rays or radiation, and (iii) developing the film irradiated with actinic rays or radiation, using a developer containing an organic solvent, in which the actinic ray-sensitive or radiation-sensitive resin composition contains a resin P and a compound that generates an acid upon irradiation with actinic rays or radiation, the resin P has a specific repeating unit Q1 represented by General Formula (q1) and a specific repeating unit Q2 represented by General Formula (q2), and the content of the repeating unit Q2 with respect to all the repeating units of the resin P is 20% by mole or more.

### CROSS-REFERENCE TO RELATED APPLICATIONS

This application is a Continuation of PCT International Application No. PCT/JP2016/060983 filed on Apr. 4, 2016, which claims priority under 35 U.S.C § 119(a) to Japanese Patent Application No. 2015-098850 filed on May 14, 2015. Each of the above application(s) is hereby expressly incorporated by reference, in its entirety, into the present application.

### BACKGROUND OF THE INVENTION

### 1. Field of the Invention

The present invention relates to a pattern forming method, a method for manufacturing an electronic device, and an actinic ray-sensitive or radiation-sensitive resin composition.

More specifically, the present invention relates to a pattern forming method which is suitable for a process for manufacturing a semiconductor such as an IC, a process for manufacturing a circuit board for a liquid crystal, a thermal head, or the like, and other lithographic processes for photofabrication; and an actinic ray-sensitive or radiation-sensitive resin composition (resist composition) used therefor. The present invention further relates to a method for manufacturing an electronic device, including the pattern forming method.

### 2. Description of the Related Art

In processes for manufacturing semiconductor devices such as an IC and an LSI, in the related art, fine processing by lithography using a resist composition has been carried out.

For example, JP2013-254084A and JP2013-057925A each disclose a resist composition containing a resin having a repeating unit in which a lactone ring is directly linked to the main chain thereof.

### SUMMARY OF THE INVENTION

In recent years, high levels of functions have been required for various types of electronic equipment, and correspondingly, additional improvement of characteristics of resist compositions for use in fine processing is required. In particular, additional improvement of depth of focus (DOF) is required.

The present inventors have formed a film (resist film) using the resist compositions described in [EXAMPLES] of JP2013-254084A and JP2013-057925A, and then carrying out exposure and development using a developer containing an organic solvent, and it has thus been found that there are cases where DOF does not satisfy the recently required levels.

Taking into consideration these problems, the present invention has been made, and has an object to provide a pattern forming method capable of providing a good DOF, a method for manufacturing an electronic device, including the pattern forming method, and an actinic ray-sensitive or radiation-sensitive resin composition.

The present inventors have conducted extensive studies to accomplish the object, and as a result, they have found that the DOF is increased by using a resin having a repeating unit in which a lactone ring is directly linked to the main chain thereof, and having a specific content of specific repeating units, thereby completing the present invention.

That is, the present invention provides [1] to [13] below.
[1] A pattern forming method comprising at least (i) forming an actinic ray-sensitive or radiation-sensitive resin composition film on a substrate, using an actinic ray-sensitive or radiation-sensitive resin composition, (ii) irradiating the film with actinic rays or radiation, and (iii) developing the film irradiated with actinic rays or radiation, using a developer containing an organic solvent, in which the actinic ray-sensitive or radiation-sensitive resin composition contains a resin P and a compound that generates an acid upon irradiation with actinic rays or radiation, the resin P has a repeating unit Q1 represented by General Formula (q1) which will be described later, and a repeating unit Q2 represented by General Formula (q2) which will be described later, and the content of the repeating unit Q2 with respect to all the repeating units of the resin P is 20% by mole or more.
[2] The pattern forming method as described in [1], in which in General Formula (q2), R₉ represents a polycyclic cycloalkyl group having 3 to 14 carbon atoms.
[3] The pattern forming method as described in [1] or [2], in which the resin P further has a repeating unit having a lactone structure different from the repeating unit Q1.
[4] The pattern forming method as described in any one of [1] to [3], in which the content of the repeating unit Q2 with respect to all the repeating units of the resin P is 40% by mole or more.
[5] The pattern forming method as described in [4], in which the content of the repeating unit Q2 with respect to all the repeating units of the resin P is 50% by mole or more.
[6] The pattern forming method as described in any one of [1] to [5], in which the resin P consists of the repeating unit Q1, the repeating unit Q2, and a repeating unit having a lactone structure different from the repeating unit Q1.
[7] A method for manufacturing an electronic device, comprising the pattern forming method as described in any one of [1] to [6].
[8] An actinic ray-sensitive or radiation-sensitive resin composition, including a resin P and a compound that generates an acid upon irradiation with actinic rays or radiation, in which the resin P has a repeating unit Q1 represented by General Formula (q1) which will be described later, and a repeating unit Q2 represented by General Formula (q2) which will be described later, and the content of the repeating unit Q2 with respect to all the repeating units of the resin P is 20% by mole or more.
[9] The actinic ray-sensitive or radiation-sensitive resin composition as described in [8], in which in General Formula (q2), R₉ represents a polycyclic cycloalkyl group having 3 to 14 carbon atoms.
[10] The actinic ray-sensitive or radiation-sensitive resin composition as described in [8] or [9], in which the resin P further has a repeating unit having a lactone structure different from the repeating unit Q1.
[11] The actinic ray-sensitive or radiation-sensitive resin composition as described in any one of [8] to [10], in which the content of the repeating unit Q2 with respect to all the repeating units of the resin P is 40% by mole or more.
[12] The actinic ray-sensitive or radiation-sensitive resin composition as described in [11], in which the content of the repeating unit Q2 with respect to all the repeating units of the resin P is 50% by mole or more.
[13] The actinic ray-sensitive or radiation-sensitive resin composition as described in any one of [8] to [12], in which the resin P consists of the repeating unit Q1, the repeating unit Q2, and a repeating unit having a lactone structure different from the repeating unit Q1.

According to the present invention, it is possible to provide a pattern forming method capable of providing a good DOF, a method for manufacturing an electronic device, including the pattern forming method, and an actinic ray-sensitive or radiation-sensitive resin composition.

### DESCRIPTION OF THE PREFERRED EMBODIMENTS

Hereinafter, suitable aspects of the present invention will be described in detail.

In citations for a group and an atomic group in the present specification, in a case where the group is denoted without specifying whether it is substituted or unsubstituted, the group includes both a group and an atomic group not having a substituent, and a group and an atomic group having a substituent. For example, an “alkyl group” which is not denoted about whether it is substituted or unsubstituted includes not only an alkyl group not having a substituent (unsubstituted alkyl group), but also an alkyl group having a substituent (substituted alkyl group).

In the present invention, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation.

Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

In the present specification, “(meth)acrylate” represents “at least one of acrylate and methacrylate.” In addition, “(meth)acrylic acid” means “at least one of acrylic acid and methacrylic acid”.

In the present specification, “(a value) to (a value)” means a range including the numerical values described before and after “to” as a lower limit value and an upper limit value, respectively.

In the present invention, the resin P contained in the actinic ray-sensitive or radiation-sensitive resin composition for forming a resist film has a repeating unit Q1 represented by General Formula (q1) which will be described later, and a repeating unit Q2 represented by General Formula (q2) which will be described later, and the content of the repeating unit Q2 with respect to all the repeating units of the resin P is 20% by mole or more.

By using such the resin P, a high depth of focus (DOF) is obtained in the present invention.

The reason therefor is not clear, but is presumed as follows.

First, it is considered that the resin having a repeating unit having a lactone structure has a reduction in its glass transition temperature by the action of an acid and a decrease in rigidity, and as a result, the diffusivity of the acid is improved. Here, the repeating unit Q1 represented by General Formula (q1) which will be described later, in which a lactone structure is directly linked to the main chain thereof, has a larger reduction in the glass transition temperature than a repeating unit in which a lactone structure is not directly linked to the main chain thereof, and thus the diffusivity of the acid is further improved.

On the other hand, in the repeating unit Q2 represented by General Formula (q2) which will be described later, a covalent bond between an oxygen atom and a quaternary carbon atom cleaves by the action of an acid, and thus, a protecting group containing the quaternary carbon atom leaves. Here, it is considered that the protecting group thus leaving is not immediately volatilized, and thus remains in the resist film for a while to help the diffusion of the acid. In the present invention, since the content of the repeating units Q2 is as large as 20% by mole or more, it is considered that the amount of the protecting group that leaves is increased, and thus, the diffusion of the acid is further improved.

Here, in the protecting group of the repeating unit Q2 represented by General Formula (q2) which will be described later, carbon atoms (R₇ to R₉ in General Formula (q2) which will be described later) bonded to quaternary carbon atoms are not combined with each other to form a ring structure. It is considered that such a protecting group has an increased interaction with the acid, as compared with a protecting group in which carbon atoms bonded to quaternary carbon atoms are combined with each other to form a ring structure, and therefore, the diffusivity of the acid is improved.

In addition, the reduction in the glass transition temperature of the repeating unit Q1 represented by General Formula (q1) which will be described later is large as mentioned above, and therefore, the acid easily moves, and the diffusivity of the acid due to the protecting group thus leaving is more improved.

In this regard, as a result of an improvement of the diffusivity of the acid, a high DOF is obtained.

Hereinafter, the actinic ray-sensitive or radiation-sensitive resin composition of the present invention will be first described, and then the pattern forming method of the present invention will be described.

[Actinic Ray-Sensitive or Radiation-Sensitive Resin Composition]

The actinic ray-sensitive or radiation-sensitive resin composition of the present invention (hereinafter also referred to as “the composition of the present invention” or “the resist composition of the present invention”) contains a resin P and a compound that generates an acid upon irradiation with actinic rays or radiation.

Here, the resin P has a repeating unit Q1 represented by General Formula (q1) which will be described later, and a repeating unit Q2 represented by General Formula (q2) which will be described later, and the content of the repeating unit Q2 with respect to all the repeating units of the resin P is 20% by mole or more.

Such the composition of the present invention is used for negative tone development (development in an exposed area remains as a pattern, while an unexposed area is removed). That is, development is carried out using the developer including an organic solvent.

[1] Resin P

The resin P has at least the repeating unit Q1 represented by General Formula (q1) which will be described later, and the repeating unit Q2 represented by General Formula (q2) which will be described later.

[1-1] Repeating Unit Q1

The repeating unit Q1 is a repeating unit represented by General Formula (q1).

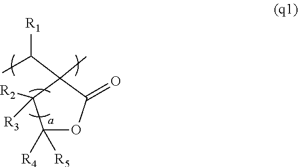

In General Formula (q1), R₁ represents a hydrogen atom or an organic group having 1 to 20 carbon atoms. R₂ to R₅ each independently represent a hydrogen atom, a fluorine atom, a hydroxy group, or an organic group having 1 to 20 carbon atoms. a represents an integer of 1 to 6. Here, R₂ and R₃, and R₄ and R₅ may be bonded to each other to form a ring structure having 3 to 10 ring members, together with a carbon atom to which they are bonded.

In General Formula (q1), R₁ represents a hydrogen atom or an organic group having 1 to 20 carbon atoms.

Examples of the organic group having 1 to 20 carbon atoms represented by R₁ in General Formula (q1) include a chain hydrocarbon group having 1 to 20 carbon atoms, an alicyclic hydrocarbon group having 3 to 20 carbon atoms, an aromatic hydrocarbon group having 6 to 20 carbon atoms, a heterocyclic group having 3 to 10 ring members, epoxy group, a cyano group, a carboxyl group, and a group represented by —R′-Q-R″, provided that R′ is a single bond or a hydrocarbon group having 1 to 20 carbon atoms, R″ is a hydrocarbon group having 1 to 20 carbon atoms, which may be substituted, or a heterocyclic group having 3 to 10 ring members, and Q is —O—, —CO—, —NH—, —SO₂—, —SO—, or a group formed by a combination thereof. Some or all of the hydrogen atoms contained in the chain hydrocarbon group, the alicyclic hydrocarbon group, and the aromatic hydrocarbon group may be substituted with, for example, a halogen atom such as a fluorine atom; or a substituent such as a cyano group, a carboxyl group, a hydroxy group, a thiol group, and a trialkylsilyl group.

Examples of the chain hydrocarbon group having 1 to 20 carbon atoms include a methyl group, an ethyl group, a propyl group, a butyl group, a pentyl group, a hexyl group, an octyl group, a decyl group, a vinyl group, and an isopropenyl group. Among these, a methyl group, an ethyl group, a propyl group, a butyl group, and a pentyl group are preferable, and a methyl group and an ethyl group are more preferable.

Examples of the alicyclic hydrocarbon group having 3 to 20 carbon atoms include monocyclic alicyclic hydrocarbon groups such as a cyclopropyl group, a cyclobutyl group, a cyclohexyl group, a cyclooctyl group, and a cyclodecyl group; and polycyclic alicyclic hydrocarbon groups such as a norbornyl group and an adamantyl group.

Examples of the aromatic hydrocarbon group having 6 to 20 carbon atoms include a phenyl group and a naphthyl group.

Examples of the heterocycle constituting the heterocyclic group having 3 to 10 ring members include a lactone ring, a cyclic carbonate, a sultone ring, a furan ring, a thiophene ring, a benzofuran ring, a benzothiophene ring, a dibenzofuran ring, a dibenzothiophene ring, and a pyridine ring. Among these, a lactone ring, a cyclic carbonate, and a sultone ring are preferable, and a lactone ring is more preferable.

Examples of the hydrocarbon group having 1 to 20 carbon atoms represented by R′ and R″ in —R′-Q-R″ include a chain hydrocarbon group having 1 to 20 carbon atoms, an alicyclic hydrocarbon group having 3 to 20 carbon atoms, and an aromatic hydrocarbon group having 6 to 20 carbon atoms. Examples of each of the hydrocarbon groups include the same groups as those exemplified as the organic group having 1 to 20 carbon atoms represented by R₁. Further, with regard to the heterocyclic group having 3 to 10 ring members represented by R″, the above description on the heterocyclic group having 3 to 10 ring members represented by R₁ can be applied.

In General Formula (q1), as R₁, a hydrogen atom is preferable from the viewpoint of the copolymerizability of a monomer providing the repeating unit Q1.

In General Formula (q1), R₂ to R₅ each independently represent a hydrogen atom, a fluorine atom, a hydroxy group, or an organic group having 1 to 20 carbon atoms.

The specific examples and suitable aspects of the organic group having 1 to 20 carbon atoms represented by R₂ to R₅ in General Formula (q1) are the same as those for the organic group having 1 to 20 carbon atoms, represented by R₁ in General Formula (q1) as mentioned above.

In General Formula (q1), R₂ and R₃, and R₄ and R₅ may be bonded to each other to form a ring structure having 3 to 10 ring members, together with a carbon atom to which they are bonded.

Examples of the ring structure having 3 to 10 ring members, formed by the mutual bonding of R₂ and R₃, and R₄ and R₅, together with a carbon atom to which they are bonded, include an alicyclic structure having an alicycle, such as cyclopropane, cyclopentane, cyclohexane, norbornane, and adamantane; and a heterocyclic structure having a ring containing a heteroatom.

Examples of the heterocyclic structure having a ring containing a heteroatom include a heterocyclic structure having a cyclic ether, a lactone ring, or a sultone ring, and other specific examples thereof include a heterocyclic structure having a ring containing an oxygen atom, such as tetrahydrofuran, tetrahydropyran, γ-butyrolactone, δ-valerolactone, oxolane, and dioxane; a heterocyclic structure having a ring containing a sulfur atom, such as tetrahydrothiophene, tetrahydrothiopyran, tetrahydrothiophene-1,1-dioxide, tetrahydrothiopyran-1,1-dioxide, and cyclopentanethione, and cyclohexanethione; and a heterocyclic structure having a ring containing a nitrogen atom, such as piperidine.

Among these, an alicyclic structure having cyclopentane, cyclohexane, or adamantane, and a heterocyclic structure having a cyclic ether, a lactone ring, or a sultone ring are preferable.

Here, the “ring structure” in the ring structure having 3 to 10 ring members, formed by the mutual bonding of R₂ and R₃, and R₄ and R₅, together with a carbon atom to which they are bonded, refers to a structure including a ring, and it may be only composed of a ring, or may also be composed of a ring and another group such as a substituent. Further, the bond in a case where R₂ and R₃, and R₄ and R₅ are bonded to each other is not limited to a bond through a chemical reaction.

In General Formula (q1), a represents an integer of 1 to 6. a is preferably an integer of 1 to 3, more preferably 1 or 2, and still more preferably 1.

Furthermore, in General Formula (q1), in a case where a is 2 or more, a plurality of R₂'s and R₃'s may be the same as or different from each other.

R₂ and R₃ are each preferably a hydrogen atom or a chain hydrocarbon group having 1 to 20 carbon atoms, and more preferably a hydrogen atom.

R₄ and R₅ are each a hydrogen atom, a chain hydrocarbon group having 1 to 20 carbon atoms, or a heterocyclic group having 3 to 10 ring members, or they are preferably bonded to each other to form a ring structure having 3 to 10 ring members, together with a carbon atom to which they are bonded.

Examples of the repeating unit Q1 represented by General Formula (q1) include, but are not limited to, repeating units represented by the following formulae. Further, R₁ in the following formulae have the same definitions as R¹ in General Formula (q1).

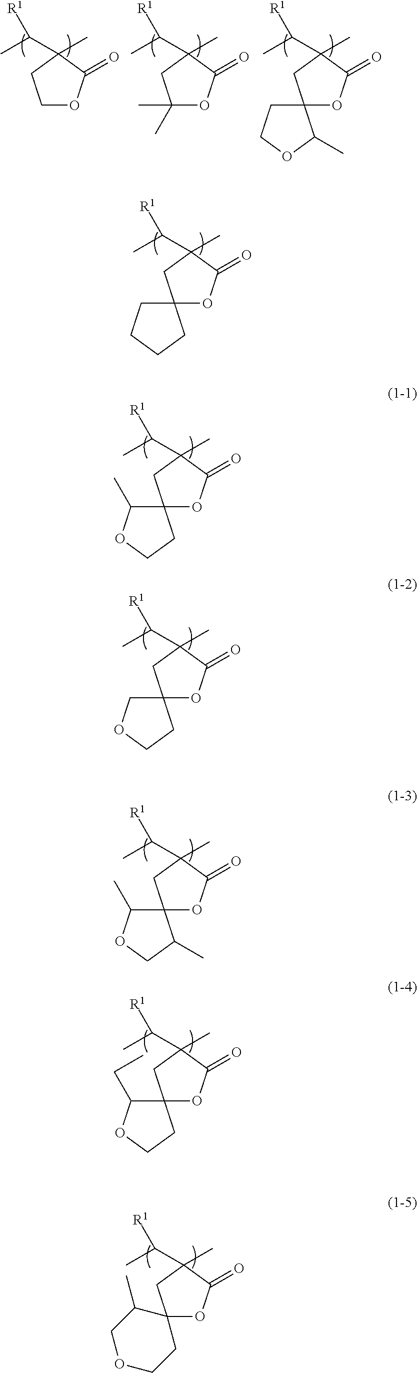

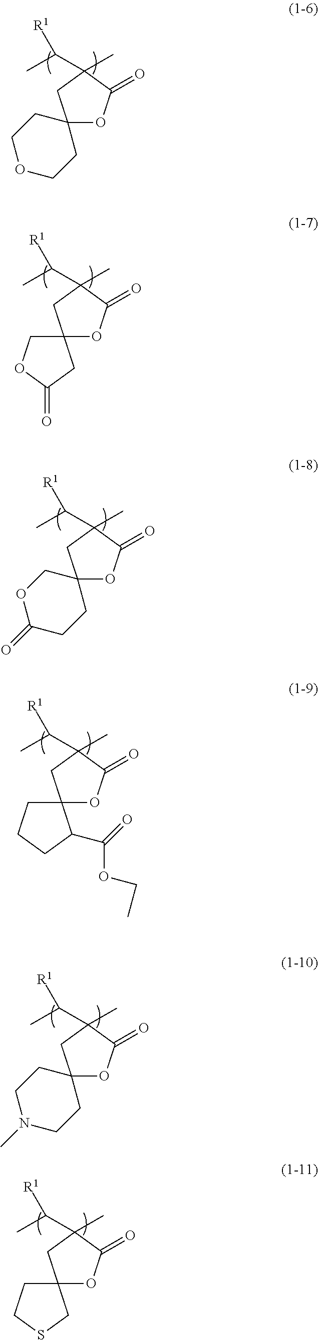

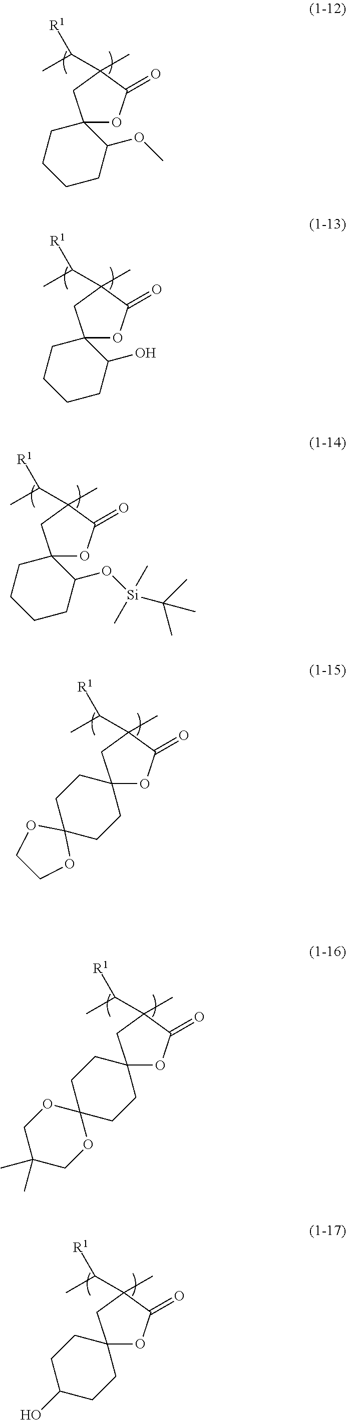

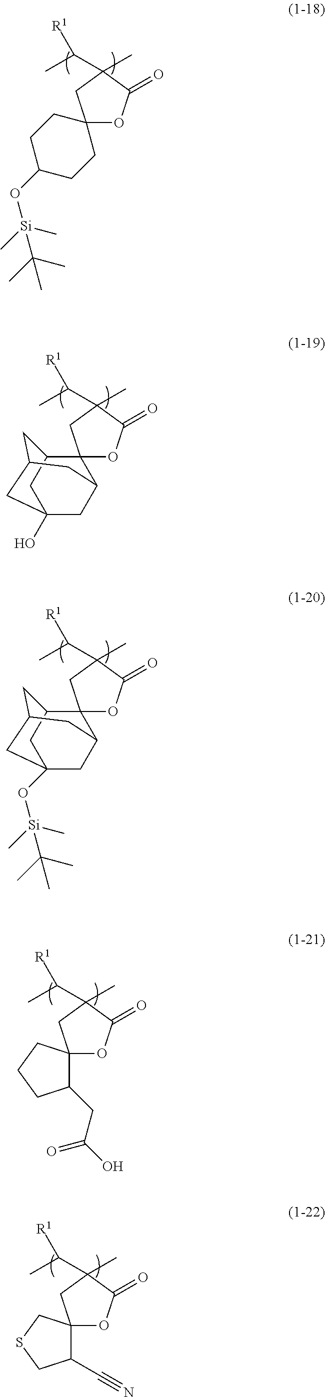

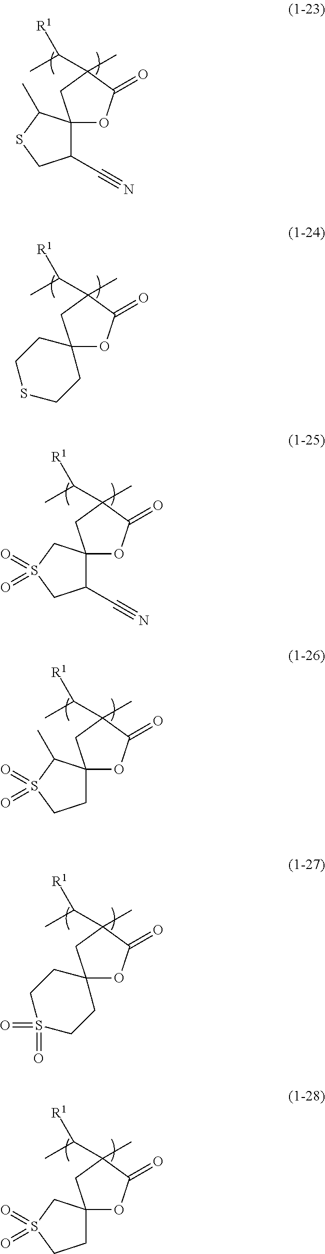

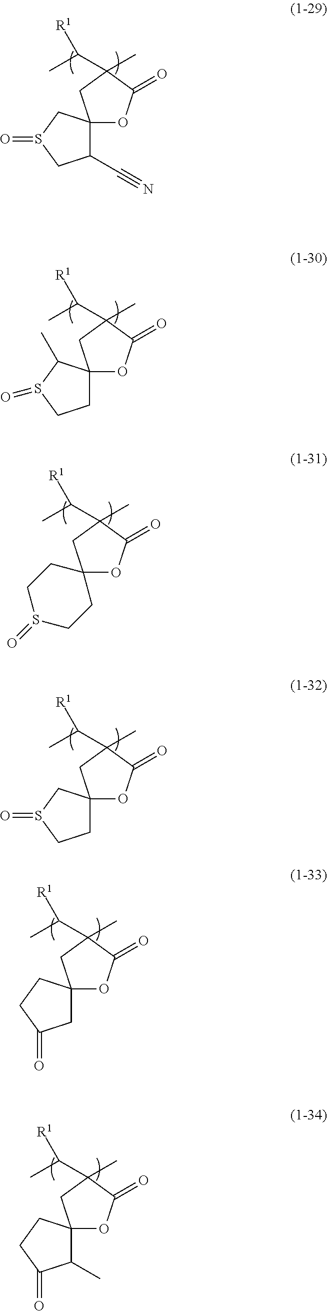

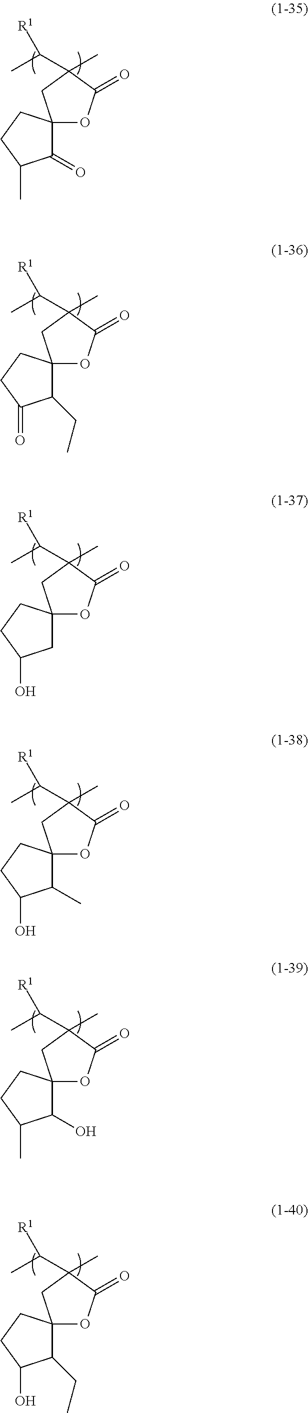

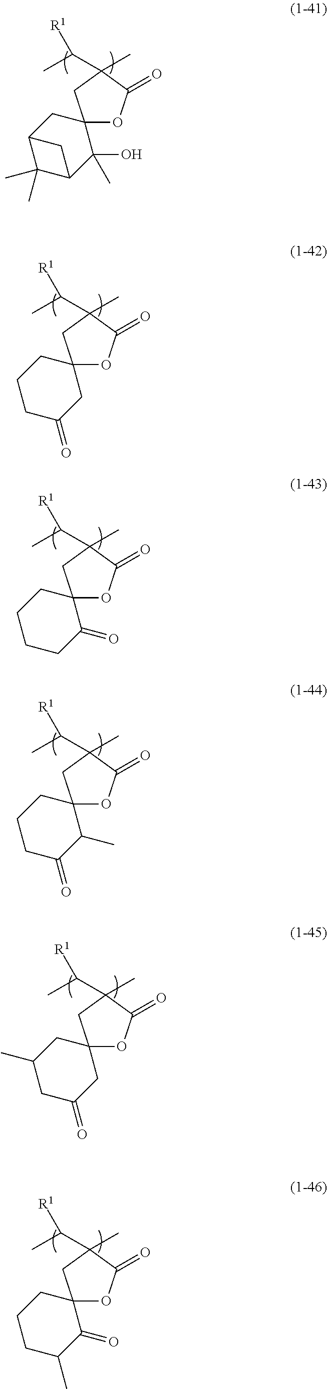

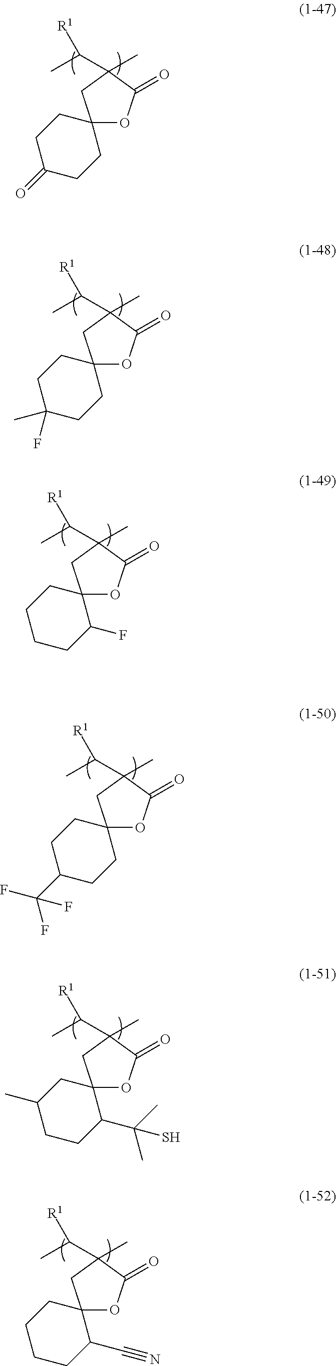

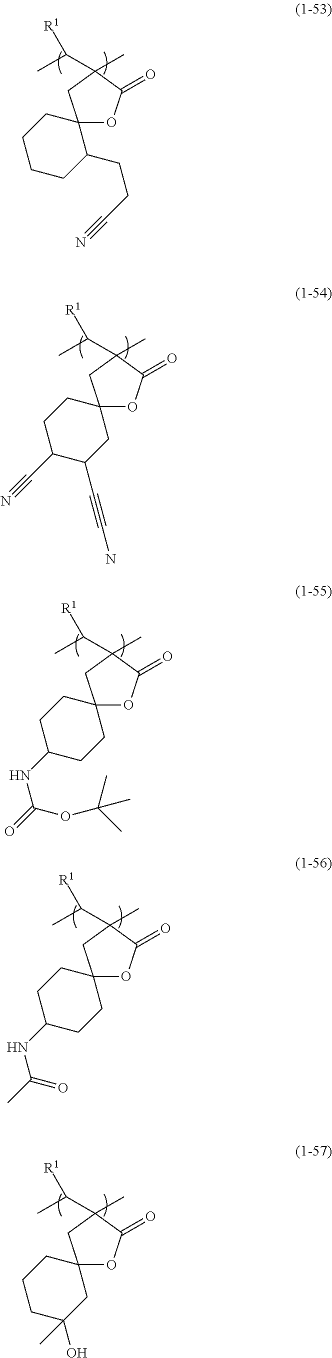

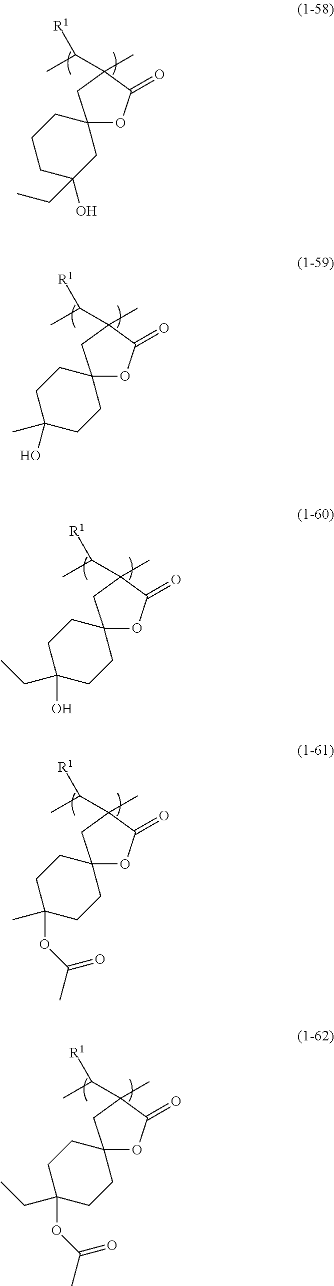

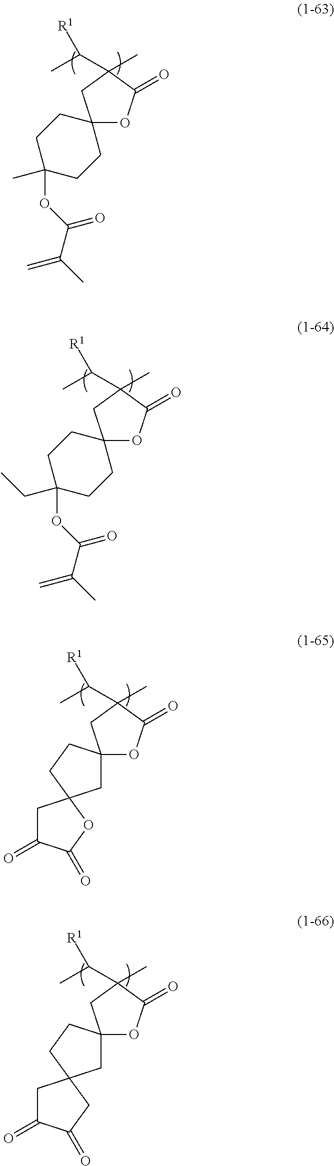

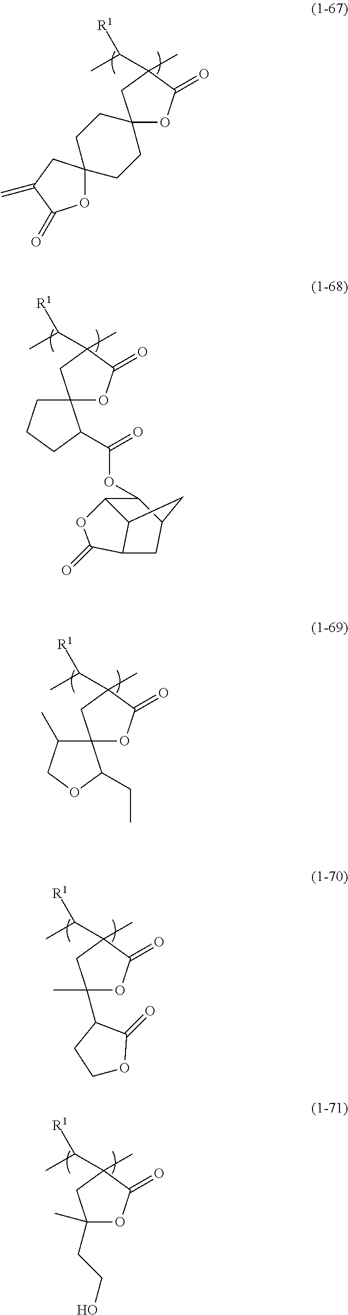

The repeating units Q1 represented by General Formula (q1) may be used singly or in combination of two or more kinds thereof.

The content of the repeating unit Q1 represented by General Formula (q1) with respect to all the repeating units of the resin P is not particularly limited, but is preferably 5% to 60% by mole, more preferably 5% to 50% by mole, and still more preferably 10% to 40% by mole.

[1-2] Repeating Unit Q2

The repeating unit Q2 is a repeating unit represented by General Formula (q2), and usually decomposes by the action of an acid to cleave a covalent bond between an oxygen atom and a quaternary carbon atom, thereby generating a carboxyl group.

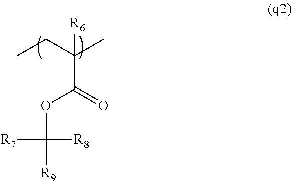

In General Formula (q2), R₆ represents a hydrogen atom or an organic group having 1 to 20 carbon atoms. R₇ and R₈ each represent a chain alkyl group which may include a branched structure having 1 to 10 carbon atoms. R₉ represents an alkyl group which may include a branched structure having 1 to 10 carbon atoms or a monocyclic or polycyclic cycloalkyl group having 3 to 14 carbon atoms.

Here, in General Formula (q2), two of R₇ to R₉ are not bonded to each other to form a ring structure.

In General Formula (q2), R₆ represents a hydrogen atom or an organic group having 1 to 20 carbon atoms.

The specific examples and suitable aspects of the organic group having 1 to 20 carbon atoms represented by R₆ in General Formula (q2) are the same as the organic group having 1 to 20 carbon atoms represented by R₁ in General Formula (q1).

In General Formula (q2), R₆ is preferably a hydrogen atom or a chain hydrocarbon group having 1 to 20 carbon atoms, and more preferably a hydrogen atom or a methyl group.

In General Formula (q2), R₇ and R₈ each represent a chain alkyl group which may include a branched structure having 1 to 10 carbon atoms.

Examples of the chain alkyl group which may include a branched structure having 1 to 10 carbon atoms represented by R₇ and R₈ in General Formula (q2) include a methyl group, an ethyl group, an n-propyl group, an iso-propyl group, an n-butyl group, an iso-butyl group, a tert-butyl group, an n-hexyl group, and an n-octyl group, and among these, a methyl group, an ethyl group, an n-propyl group, and an iso-propyl group are preferable.

In General Formula (q2), R₉ represents an alkyl group which may include a branched structure having 1 to 10 carbon atoms or a monocyclic or polycyclic cycloalkyl group having 3 to 14 carbon atoms.

Examples of the alkyl group which may include a branched structure having 1 to 10 carbon atoms represented by R₉ in General Formula (q2) include a methyl group, an ethyl group, an n-propyl group, an isopropyl group, an n-butyl group, an isobutyl group, a tert-butyl group, an n-hexyl group, and an n-octyl group, and among these, a methyl group, an ethyl group, an n-propyl group, and an isopropyl group are preferable.

Examples of the monocyclic or polycyclic cycloalkyl group having 3 to 14 carbon atoms represented by R₉ in General Formula (q2) include a monocyclic cycloalkyl group having 3 to 14 carbon atoms, such as a cyclopentyl group and a cyclohexyl group; norbornyl group; and a polycyclic cycloalkyl group having 3 to 14 carbon atoms, such as a tetracyclodecanyl group, a tetracyclododecanyl group, and an adamantyl group, and among these, a polycyclic cycloalkyl group having 3 to 14 carbon atoms is preferable, and an adamantyl group is more preferable.

In General Formula (q2), R₉ is preferably a monocyclic or polycyclic cycloalkyl group having 3 to 14 carbon atoms, and more preferably a polycyclic cycloalkyl group having 3 to 14 carbon atoms.

Examples of the repeating unit Q2 represented by General Formula (q2) include, but are not limited to, repeating units represented by the following formulae. Further, Xa₁ in the following formulae has the same definition as R₆ in General Formula (q2). Further, R₆ to R₈ in the following formulae have the same definitions as R₆ to R₈ in General Formula (q2).

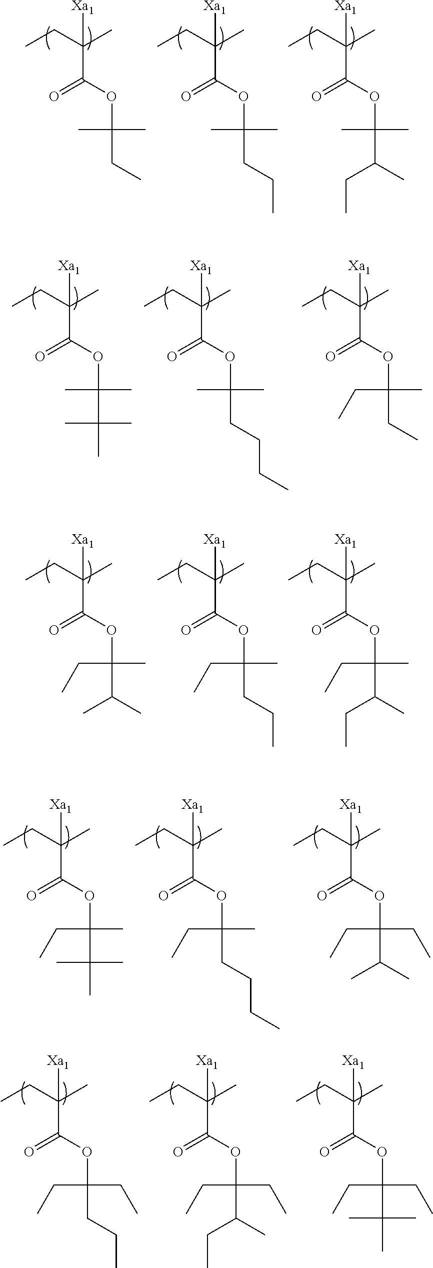

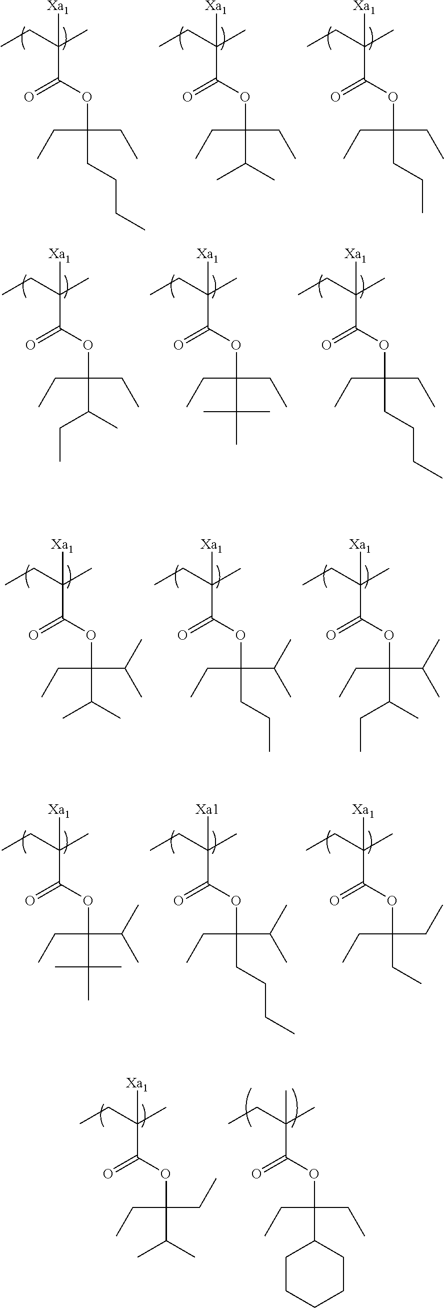

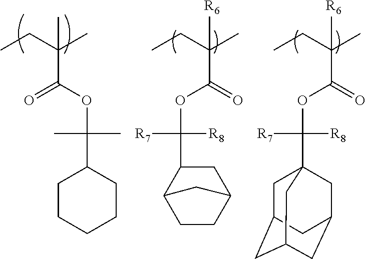

The repeating units Q2 represented by General Formula (q2) may be used singly or in combination of two or more kinds thereof.

The content of the repeating unit Q2 represented by General Formula (q2) with respect to all the repeating units of the resin P is 20% by mole or more. As mentioned above, in the present invention, since the content of the repeating units Q2 is as large as 20% by mole or more, DOF is excellent. Further, LWR is also improved.

For a reason that DOF and LWR are further improved, the content of the repeating unit Q2 represented by General Formula (q2) with respect to all the repeating units of the resin P is preferably 40% by mole or more, and more preferably 50% by mole or more. On the other hand, the upper limit is not particularly limited, but is, for example, 80% by mole or less.

The total content of the repeating unit Q1 represented by General Formula (q1) and the repeating unit Q2 represented by General Formula (q2) with respect to all the repeating units of the resin P is preferably 25% by mole to 100% by mole, more preferably 30% by mole to 100% by mole, still more preferably 40% by mole to 100% by mole, and particularly preferably 50% by mole to 100% by mole.

[1-3] Repeating Unit Q3

The resin P may further have a repeating unit Q3.

The repeating unit Q3 is a repeating unit represented by General Formula (q3), which is a repeating unit different from the above-mentioned repeating unit Q2 represented by General Formula (q2). The repeating unit Q3 usually decomposes by the action of an acid to cleave a covalent bond between an oxygen atom and a quaternary carbon atom, thereby generating a carboxyl group.

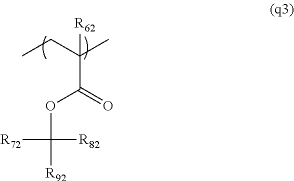

In General Formula (q3), R₆₂ represents a hydrogen atom or an organic group having 1 to 20 carbon atoms. R₇₂ and R₈₂ each represent a chain alkyl group which may include a branched structure having 1 to 10 carbon atoms. R₉₂ represents an alkyl group which may include a branched structure having 1 to 10 carbon atoms or a monocyclic or polycyclic cycloalkyl group having 3 to 14 carbon atoms.

The specific examples and suitable aspects of R₆₂ in General Formula (q3) are the same as R₆ in General Formula (q2) as mentioned above.

The specific examples and suitable aspects of R₇₂ to R₉₂ in General Formula (q3) are each the same as R₇ to R₉ in General Formula (q2) as mentioned above, except that two of R₇₂ to R₉₂ are not bonded to each other to form a ring structure.

In General Formula (q3), at least two of R₇₂, . . . , or R₉₂ may be bonded to each other to form a ring structure, together with a carbon atom to which they are bonded, and they preferably form a ring structure having 3 to 20 carbon atoms, and more preferably form a ring structure having 3 to 14 carbon atoms. Examples of this ring structure include a monocyclic ring structure such as a cyclopropyl group, a cyclobutyl group, a cyclohexyl group, a cyclooctyl group, and a cyclodecyl group; and a polycyclic ring structure such as a norbornyl group and an adamantyl group.

Suitable examples of the repeating unit Q3 include a repeating unit represented by General Formula (q31) and a repeating unit represented by General Formula (q32), each shown below.

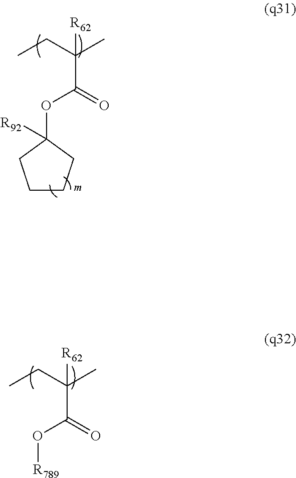

In General Formula (q31), R₆₂ and R₉₂ have the same definitions as R₆₂ and R₉₂ in General Formula (q3), and m represents an integer of 1 to 8, and is preferably an integer of 1 to 4.

In General Formula (q32), R₆₂ has the same definition as R₆₂ in General Formula (q3).

Furthermore, in General Formula (q32), R₇₈₉ represents a ring structure. A ring structure having 3 to 20 carbon atoms represented by R₇₈₉ is preferable, and a ring structure having 3 to 14 carbon atoms is more preferable, and examples thereof include a polycyclic ring structure such as a norbornyl group and an adamantyl group.

The repeating units Q3 may be used singly or in combination of two or more kinds thereof.

In a case where the resin P has the repeating unit Q3, the content of the repeating unit Q3 with respect to all the repeating units of the resin P is preferably 50% by mole or less, and more preferably 40% by mole or less. The lower limit is not particularly limited, but is, for example, 10% by mole or more.

[1-4] Repeating Unit Having Lactone Structure

The resin P preferably further has a repeating unit (hereinafter simply also referred to as “a repeating unit having a lactone structure” or “a repeating unit (a)”) having a lactone structure different from the above-mentioned repeating unit Q1.

The repeating unit (a) is preferably a repeating unit derived from a (meth)acrylic acid derivative monomer.

The repeating units (a) may be used singly or in combination of two or more kinds thereof, but are preferably used singly.

The content of the repeating unit (a) with respect to all the repeating units of the resin P varies depending on the structure included the repeating unit (a), but may be, for example, 3% to 80% by mole, and is preferably 3% to 60% by mole.

The lactone structure is preferably a 5- to 7-membered ring lactone structure, with a 5- to 7-membered ring lactone structure to which another ring structure is fused so as to form a bicyclo structure or a spiro structure being preferable. The resin still more preferably has a repeating unit having a lactone structure represented by any one of General Formulae (LC1-1) to (LC1-17). The preferred lactone structure is (LC1-1), (LC1-4), (LC1-5), or (LC1-8), with (LC1-4) being more preferable.

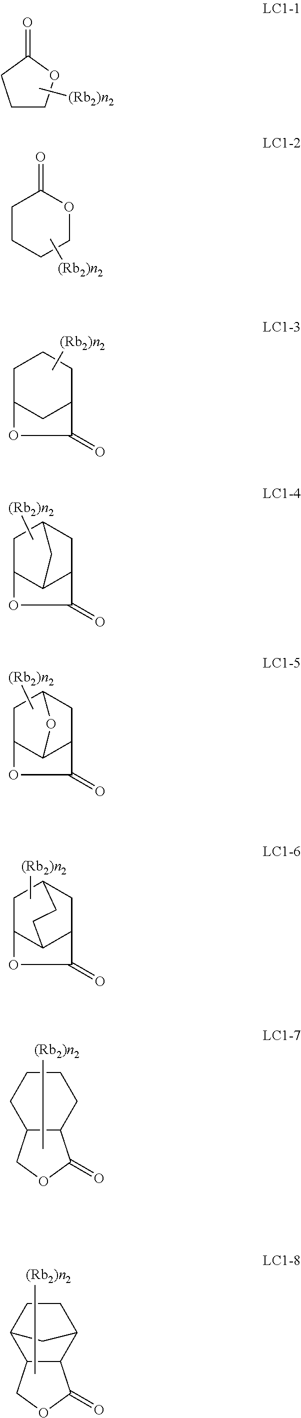

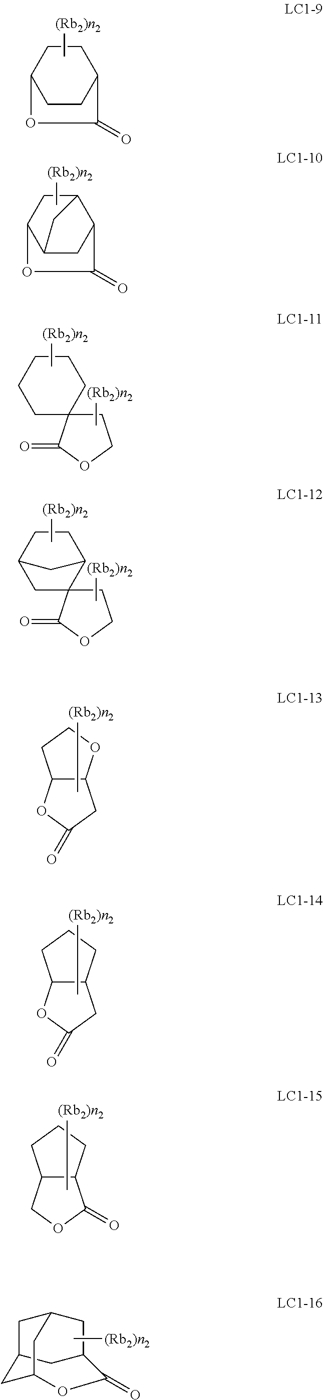

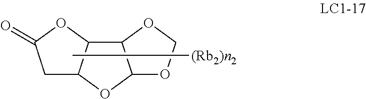

The lactone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. When n₂ is 2 or more, the substituents (Rb₂) which are present in plural numbers may be the same as or different from each other, and further, the substituents (Rb₂) which are present in plural numbers may be bonded to each other to form a ring.

[1-5] Repeating Unit Having Sultone Structure

The resin P may have a repeating unit (hereinafter simply also referred to as “a repeating unit (b)”) having a sultone (cyclic sulfonic acid ester) structure.

The repeating unit (b) is preferably a repeating unit derived from a (meth)acrylic acid derivative monomer.

The repeating units (b) may be used singly or in combination of two or more kinds thereof, but are preferably used singly.

The content of the repeating unit (b) with respect to all the repeating units of the resin P varies depending on the structure included the repeating unit (b), but may be, for example, 3% to 80% by mole, and is preferably 3% to 60% by mole.

The sultone structure is preferably a 5- to 7-membered ring sultone structure, with a 5- to 7-membered ring sultone structure to which another ring structure is fused so as to form a bicyclo structure or a spiro structure being preferable. The resin more preferably has a repeating unit having a sultone structure represented by any one of General Formulae (SL1-1) and (SL1-2). Further, the sultone structure may be directly bonded to the main chain.

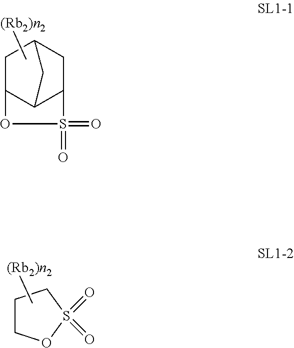

The sultone structure moiety may or may not have a substituent (Rb₂). In the formula, the substituent (Rb₂) and n₂ have the same definitions as the substituent (Rb₂) and n₂, respectively, of the lactone structure moiety as mentioned above.

It is preferable that the resin P contains a repeating unit having a sultone structure represented by General Formula (III′).

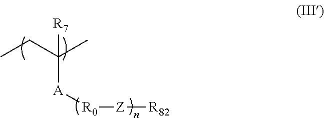

A, R₀, Z, n, and R₇ in Formula (III′) have the same definitions as A, R₀, Z, n, and R₇, respectively, in Formula (III) as mentioned above.

R₈₂ in Formula (III′) represents a monovalent organic group having a sultone structure.

The monovalent organic group having a sultone structure represented by R₈₂ is not limited as long as it has a sultone structure, and specific examples thereof include the sultone structures represented by General Formula (SL1-1) and (SL1-2) as mentioned above. Further, n₂ in (SL1-1) and (SL1-2) is more preferably 2 or less.

In addition, R₈₂ is preferably a unsubstituted monovalent organic group having a sultone structure, or a monovalent organic group having a sultone structure having a methyl group, a cyano group, or an alkoxycarbonyl group as a substituent, and more preferably a monovalent organic group having a sultone structure (cyanosultone) having a cyano group as a substituent.

[1-6] Repeating Unit Having Carbonate Structure

The resin P may have a repeating unit having a carbonate structure.

The carbonate structure (cyclic carbonic acid ester structure) is a structure having a ring including a bond represented by —O—C(═O)—O— as an atomic group constituting the ring. The ring including a bond represented by —O—C(═O)—O— as an atomic group constituting the ring is preferably a 5- to 7-membered ring, and most preferably a 5-membered ring. Such a ring may be fused with another ring to form a fused ring.

It is preferable that the resin P contains a repeating unit represented by General Formula (A-1) as a repeating unit having a carbonate structure (cyclic carbonic acid ester structure).

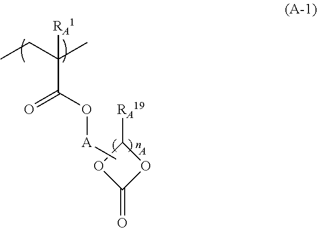

In General Formula (A-1), R_{A}¹ represents a hydrogen atom or an alkyl group.

R_{A}¹⁹'s each independently represent a hydrogen atom or a chain hydrocarbon group.

A represents a single bond, a divalent or trivalent chain hydrocarbon group, a divalent or trivalent alicyclic hydrocarbon group, or a divalent or trivalent aromatic hydrocarbon group, and in a case where A is trivalent, a carbon atom included in A are bonded to the carbon atom constituting a cyclic carbonic acid ester to form a ring structure.

n_{A} represents an integer of 2 to 4.

In General Formula (A-1), R_{A}¹ represents a hydrogen atom or an alkyl group. The alkyl group represented by R_{A}¹ may have a substituent such as a fluorine atom. R_{A}¹ preferably represents a hydrogen atom, a methyl group, or a trifluoromethyl group, and more preferably a methyl group.

R_{A}¹⁹'s each independently represent a hydrogen atom or a chain hydrocarbon group. The chain hydrocarbon group represented by R_{A}¹⁹ is preferably a chain hydrocarbon group having 1 to 5 carbon atoms. Examples of the “chain hydrocarbon group having 1 to 5 carbon atoms” include linear alkyl groups having 1 to 5 carbon atoms, such as a methyl group, an ethyl group, a propyl group, and a butyl group; and branched alkyl groups having 3 to 5 carbon atoms, such as an isopropyl group, an isobutyl group, and a t-butyl group. The chain hydrocarbon groups may have a substituent such as a hydroxyl group.

R_{A}¹⁹ most preferably represents a hydrogen atom.

In General Formula (A-1), n_{A} represents an integer of 2 to 4. That is, in a case of n=2 (an ethylene group), the cyclic carbonic acid ester is a 5-membered ring structure; in a case of n=3 (a propylene group), the cyclic carbonic acid ester is a 6-membered ring structure; and in a case of n=4 (a butylene group), the cyclic carbonic acid ester is a 7-membered ring structure. For example, the repeating unit (A-1a) which will be described later is a 5-membered ring structure, and (A-1j) is an example of the 6-membered ring structure.

n_{A} is preferably 2 or 3, and more preferably 2.

In General Formula (A-1), A represents a single bond, divalent or trivalent chain hydrocarbon group, a divalent or trivalent alicyclic hydrocarbon group, or a divalent or trivalent aromatic hydrocarbon group.

The divalent or trivalent chain hydrocarbon group is preferably a divalent or trivalent chain hydrocarbon group having 1 to 30 carbon atoms.

The divalent or trivalent alicyclic hydrocarbon group is preferably a divalent or trivalent alicyclic hydrocarbon group having 3 to 30 carbon atoms.

The divalent or trivalent aromatic hydrocarbon group is preferably a divalent or trivalent aromatic hydrocarbon group having 6 to 30 carbon atoms.

In a case where A is a single bond, the oxygen atom of an (alkyl)acrylic acid (typically a (meth)acrylic acid) to which R_{A}¹ is bonded at the α-position constituting a polymer is directly bonded to the carbon atom constituting the cyclic carbonic acid ester.

The “chain hydrocarbon group” is used to mean a hydrocarbon group that does not include a cyclic structure in the main chain, and includes only a chain structure. Examples of the “divalent chain hydrocarbon group having 1 to 30 carbon atoms” include linear alkylene groups such as a methylene group, an ethylene group, a 1,2-propylene group, a 1,3-propylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, and an eicosylene group; and branched alkylene groups such as a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group. Examples of the “trivalent chain hydrocarbon group having 1 to 30 carbon atoms” include a group produced by elimination of one hydrogen atom from the functional group.

Examples of the structure in a case where A is the chain hydrocarbon group include a structure in which the oxygen atom of an (alkyl)acrylic acid (typically a (meth)acrylic acid) to which R_{A}¹ is bonded at the α-position constituting a polymer is bonded to the carbon atom constituting the cyclic carbonic acid ester through a linear alkylene group having 1 to 5 carbon atoms (the repeating units (A-1a) to (A-1f) which will be described later). In this structure, a cyclic structure may be included as a substituent of A (the repeating unit (A-1p) which will be described later).

A carbon atom included in A and a carbon atom constituting the cyclic carbonic acid ester may be bonded to each other to form a ring structure. That is, the cyclic carbonic acid ester may form a part of a fused ring or a spiro ring. A fused ring is formed in a case where two carbon atoms of the cyclic carbonic acid ester are included in the ring structure, and a spiro ring is formed in a case where only one carbon atom of the cyclic carbonic acid ester is included. The repeating units (A-1g), (A-1q), (A-1t), (A-1u), (A-1i), (A-1r), (A-1s), (A-1v), and (A-1w) which will be described later are examples in which a fused ring including a carbon atom included in A and two carbon atoms constituting the cyclic carbonic acid ester is formed. On the other hand, the repeating unit (A-1j) which will be described later is an example in which a spiro ring is formed by a carbon atom included in A and one carbon atom constituting the cyclic carbonic acid ester. In addition, the ring structure may be a hetero ring (the repeating units (A-1q to A-1v) which will be described later).

The “alicyclic hydrocarbon group” means a hydrocarbon group that includes only an alicyclic hydrocarbon structure and does not include an aromatic ring structure, as a ring structure. Here, the alicyclic hydrocarbon group does not necessarily need to be only composed of an alicyclic hydrocarbon structure, but may partly include a chain structure.

Examples of the “divalent alicyclic hydrocarbon group” include monocyclic cycloalkylene groups having 3 to 10 carbon atoms, such as a 1,3-cyclobutylene group, a 1,3-cyclopentylene group, a 1,4-cyclohexylene group, and a 1,5-cyclooctylene group; and polycyclic cycloalkylene groups such as a 1,4-norbornylene group, a 2,5-norbornylene group, a 1,5-adamantylene group, and a 2,6-adamantylene group. Examples of the “trivalent alicyclic hydrocarbon group” include a group produced by elimination of one hydrogen atom from the functional groups, and the like.

Examples of the structure in a case where A is the alicyclic hydrocarbon group include a structure in which the oxygen atom of an (alkyl)acrylic acid (typically a (meth)acrylic acid) to which R_{A}¹ is bonded at the α-position constituting a polymer is bonded to the carbon atom constituting the cyclic carbonic acid ester through a cyclopentylene group (the repeating units (A-1g) and (A-1h) which will be described later), through a norbornylene group (the repeating units (A-1j), (A-1k), and (A-1l) which will be described later), or through a substituted tetradecahydrophenanthryl group (the repeating unit (A-1n) which will be described later).

Moreover, the repeating units (A-1k) and (A-1l) which will be described later are examples in which a fused ring which includes a carbon atom included in A and two carbon atoms constituting the cyclic carbonic acid ester is formed. On the other hand, the repeating units (A-1j) and (A-1n) which will be described later are examples in which a spiro ring is formed by a carbon atom included in A and one carbon atom constituting the cyclic carbonic acid ester.

The “aromatic hydrocarbon group” means a hydrocarbon group that includes an aromatic ring structure as a ring structure. Here, the aromatic hydrocarbon group does not necessarily need to be only composed of an aromatic ring structure, but may include a chain structure or an alicyclic hydrocarbon structure in a part thereof.

Examples of the “divalent aromatic hydrocarbon group” include arylene groups such as a phenylene group, a tolylene group, a naphthylene group, a phenanthrylene group, and an anthrylene group. Examples of the “trivalent aromatic hydrocarbon group” include a group produced by elimination of one hydrogen atom from the functional groups.

Examples of the structure in which A is the aromatic hydrocarbon group include a structure in which the oxygen atom of an (alkyl)acrylic acid (typically a (meth)acrylic acid) to which R_{A}¹ is bonded at the α-position constituting a polymer is bonded to the carbon atom constituting the cyclic carbonic acid ester through a benzylene group (the repeating unit (A-1o) which will be described later). The repeating unit (A-1o) is an example in which a fused ring including a carbon atom included in A and two carbon atoms constituting the cyclic carbonic acid ester is formed.

A preferably represents a divalent or trivalent chain hydrocarbon group, or a divalent or trivalent alicyclic hydrocarbon group, more preferably represents a divalent or trivalent chain hydrocarbon group, and still more preferably represents a linear alkylene group having 1 to 5 carbon atoms.

The monomer can be synthesized by the method known in the related art, for example, described in Tetrahedron Letters, Vol. 27, No. 32 p. 3741 (1986), and Organic Letters, Vol. 4, No. 15 p. 2561 (2002).

Specific examples of the repeating unit represented by General Formula (A-1) (repeating units (A-1a) to (A-1w)) are shown below, but the present invention is not limited thereto.

Furthermore, R_{A}¹ in the following specific examples has the same definition as R_{A}¹ in General Formula (A-1).

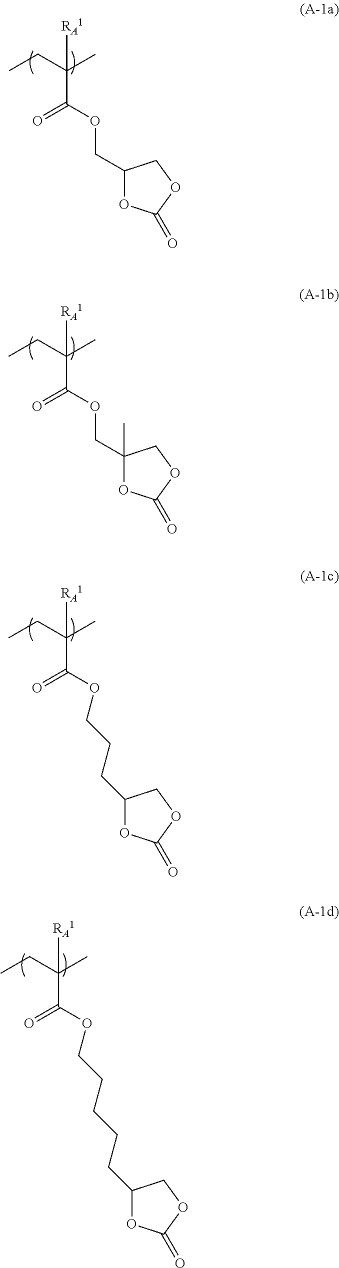

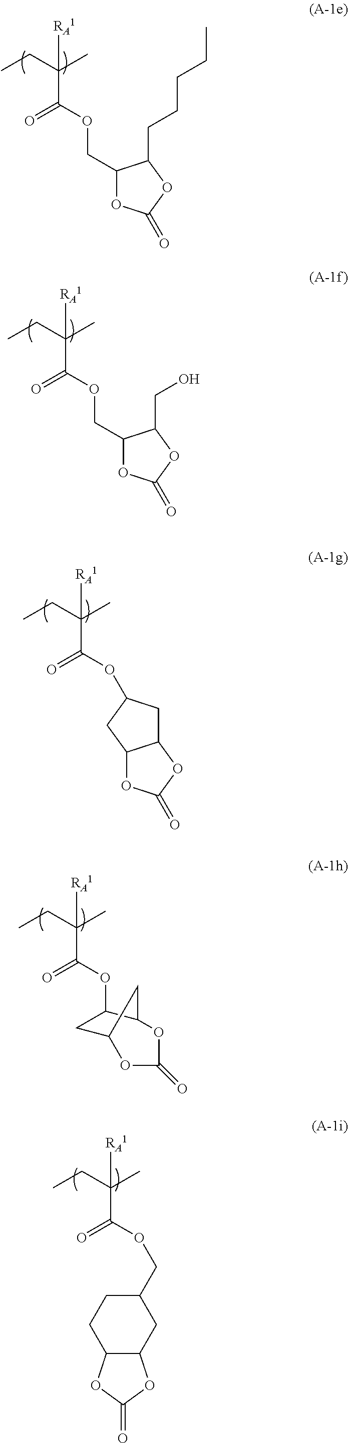

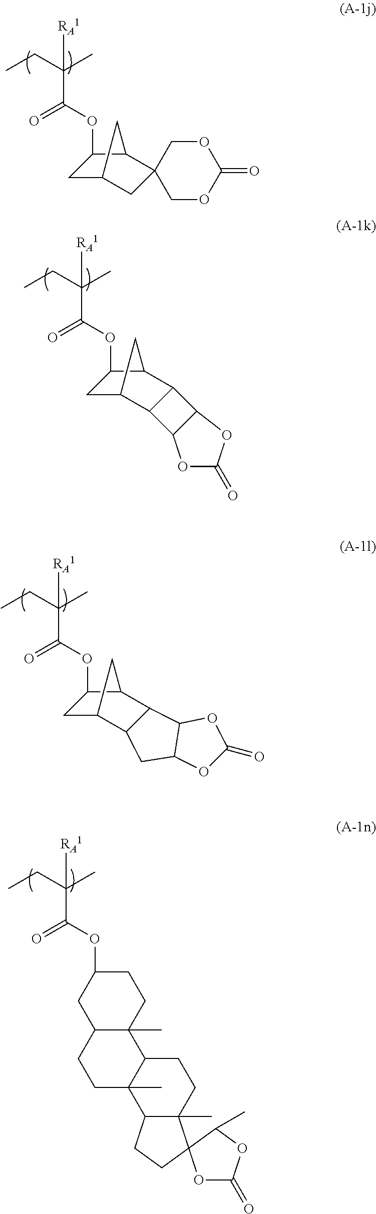

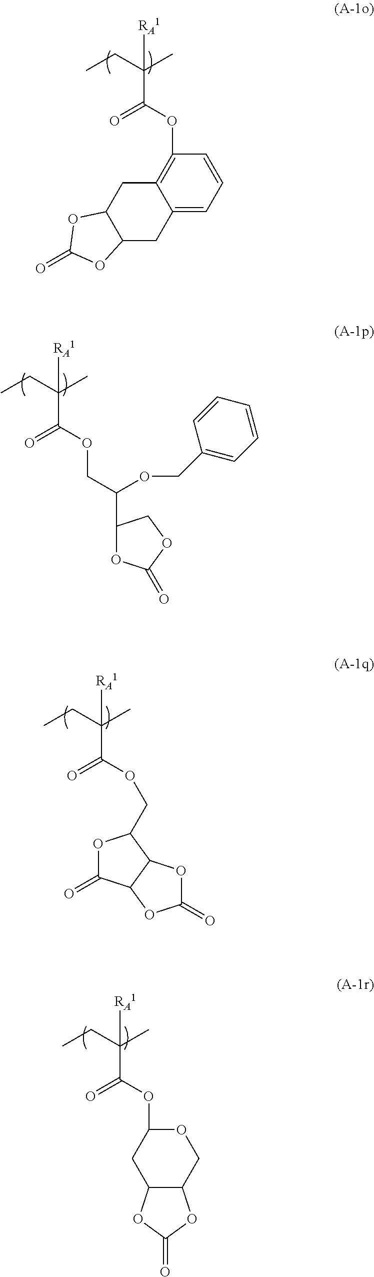

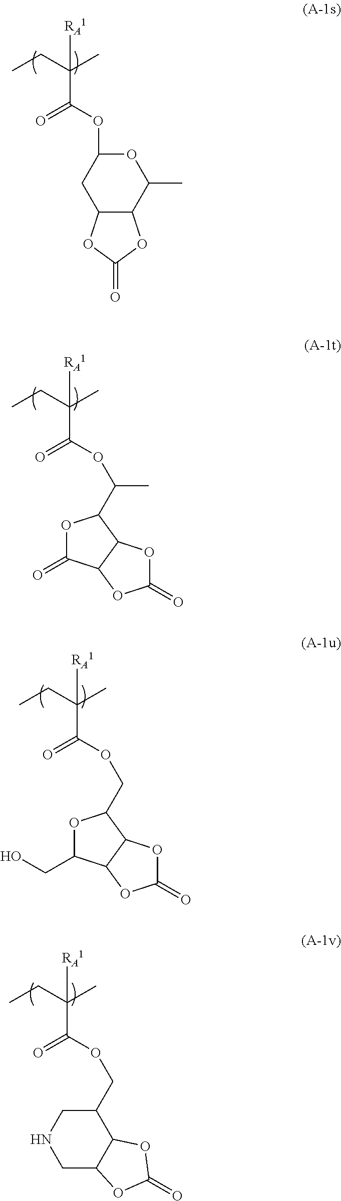

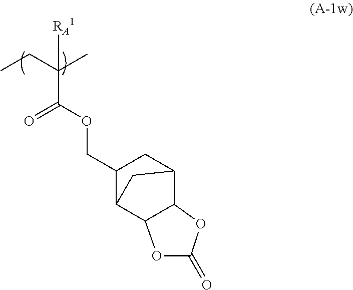

The resin P may include only one kind or two or more kinds of the repeating unit represented by General Formula (A-1).

In the resin P, the content of the repeating units having a carbonate structure (cyclic carbonic acid ester structure) (preferably a repeating unit represented by General Formula (A-1)) is preferably 3% to 80% by mole, more preferably 3% to 60% by mole, and still more preferably 3% to 30% by mole, with respect to all the repeating units constituting the resin P.

[1-7] Other Repeating Units

The resin P may include other repeating units.

For example, the resin P may include a repeating unit having a hydroxyl group or a cyano group. Examples of such a repeating unit include the repeating units described in paragraphs <0081> to <0084> of JP2014-098921A.

Furthermore, the resin P may have a repeating unit having an alkali-soluble group. Examples of the alkali-soluble group include a carboxyl group, a sulfonamido group, a sulfonylimido group, a bisulfonylimido group, and an aliphatic alcohol group with the α-position being substituted with an electron-withdrawing group (for example, a hexafluoroisopropanol group). Examples of the repeating unit having an alkali-soluble group include the repeating units described in paragraphs <0085> and <0086> of JP2014-098921A.

Moreover, the resin P can have a repeating unit which has an alicyclic hydrocarbon structure not having a polar group (for example, an alkali-soluble group, a hydroxyl group, and a cyano group), and does not exhibit acid decomposability. Examples of such a repeating unit include the repeating units described in paragraphs <0114> to <0123> of JP2014-106299A.

Furthermore, the resin P may include the repeating units described in, for example, paragraphs <0045> to <0065> of JP2009-258586A.

In addition to the repeating units, the resin P used in the composition of the present invention can have a variety of repeating units. Examples of such repeating units include, but are not limited to, repeating units corresponding to the following monomers.

Examples of such a monomer include a compound having one addition-polymerizable unsaturated bond selected from acrylic esters, methacrylic esters, acrylamides, methacrylamides, allyl compounds, vinyl ethers, vinyl esters, and the like.

In addition to these, an addition-polymerizable unsaturated compound that is copolymerizable with the monomers corresponding to various repeating structural units as described above may be copolymerized.

In the resin P used in the composition of the present invention, the molar ratio of the respective repeating structural unit contents may be appropriately set.

Hereinabove, the repeating units which may be contained in the resin P have been described.

The resin P is not particularly limited as long as it has the repeating unit Q1 and the repeating unit Q2, and the content of the repeating units Q2 is 20% by mole or more as described above, it preferably further has the above-mentioned repeating unit having a lactone structure different from the repeating unit Q1.

More preferably, the resin P consists of the repeating unit Q1, the repeating unit Q2, and a repeating unit having a lactone structure different from the repeating unit Q1.

When the composition of the present invention is for ArF exposure, it is preferable that the resin P used in the composition of the present invention does not substantially have an aromatic group in terms of transparency to ArF light. More specifically, the proportion of repeating units having an aromatic group in all the repeating units of the resin P is preferably 5% by mole or less, and more preferably 3% by mole or less, and ideally, the proportion is more preferably 0% by mole of all the repeating units, that is, the resin P does not have a repeating unit having an aromatic group. Further, it is preferable that the resin P has a monocyclic or polycyclic alicyclic hydrocarbon structure.

Furthermore, it is preferable that the resin P contains neither a fluorine atom nor a silicon atom from the viewpoint of compatibility with a hydrophobic resin (D) which will be described later.

The resin P used in the composition of the present invention is preferably a resin in which all the repeating units are composed of (meth)acrylate-based repeating units. In this case, any of a resin in which all the repeating units may be methacrylate-based repeating units, a resin in which all the repeating units may be acrylate-based repeating units, or a resin in which all the repeating units may be composed of methacrylate-based repeating units and acrylate-based repeating units can be used, but a resin in which the acrylate-based repeating units preferably accounts for 50% by mole or less with respect to all the repeating units is preferable.

The resin P in the present invention can be synthesized in accordance with an ordinary method (for example, radical polymerization). Examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable.

Examples of the reaction solvent include ethers such as tetrahydrofuran, 1,4-dioxane, and diisopropyl ether; ketones such as methyl ethyl ketone and methyl isobutyl ketone; ester solvents such as ethyl acetate; amide solvents such as dimethyl formamide and dimethyl acetamide, and a solvent used the composition of the present invention, such as propylene glycol monomethyl ether acetate, propylene glycol monomethyl ether, and cyclohexanone, which will be described later. It is more preferable to perform polymerization using the same solvent as the solvent used in the composition of the present invention. Thus, generation of the particles during storage can be suppressed.

It is preferable that the polymerization reaction is carried out in an inert gas atmosphere such as nitrogen and argon. As the polymerization initiator, commercially available radical initiators (an azo-based initiator, peroxide, or the like) are used to initiate the polymerization. As the radical initiator, an azo-based initiator is preferable, and the azo-based initiator having an ester group, a cyano group, or a carboxyl group is more preferable. Preferred examples of the initiator include azobisisobutyronitrile, azobisdimethylvaleronitrile, and dimethyl 2,2′-azobis(2-methyl propionate). The initiator is added or added in portionwise, as desired, a desired polymer is recovered after the reaction is completed, the reaction mixture is poured into a solvent, and then a method such as powder or solid recovery is used. The concentration of the reactant is 5% to 50% by mass and preferably 10% to 30% by mass. The reaction temperature is normally 10° C. to 150° C., preferably 30° C. to 120° C., and more preferably 60° C. to 100° C.

The weight-average molecular weight (Mw) of the resin P is preferably 1,000 to 200,000, more preferably 2,000 to 20,000, still more preferably 3,000 to 15,000, and particularly preferably 3,000 to 11,000. By setting the weight-average molecular weight to 1,000 to 200,000, it is possible to prevent the deterioration of heat resistance or dry-etching resistance, and also prevent the deterioration of film forming properties due to deteriorated developability or increased viscosity.

The dispersity (molecular weight distribution) which is a ratio (Mw/Mn) of the weight-average molecular weight (Mw) to the number-average molecular weight (Mn) for the resin P is usually 1.0 to 3.0, preferably in the range of 1.0 to 2.6, more preferably in the range of 1.0 to 2.0, and still more preferably in the range of 1.1 to 2.0. As the molecular weight distribution is smaller, the resolution and the resist shape are better, the side wall of the resist pattern is smoother, and the roughness is better.

In the present specification, the weight-average molecular weight (Mw) and the number-average molecular weight (Mn) are values in terms of polystyrene, determined by a gel permeation chromatography (GPC) method, using HLC-8120 (manufactured by Tosoh Corporation). Further, TSK gel Multipore HXL-M (manufactured by Tosoh Corporation, 7.8 mmID×30.0 cm) is used as a column, and tetrahydrofuran (THF) is used as a developing solvent.

The content of the resin P in the entire composition is preferably 30% to 99% by mass, and more preferably 50% to 95% by mass, with respect to the total solid contents.

Furthermore, the resin P may be used singly or in combination of two or more kinds thereof.

[2] Compound that Generates Acid Upon Irradiation with Actinic Rays or Radiation

The composition of the present invention contains a compound that generates an acid upon irradiation with actinic rays or radiation (hereinafter also referred to as “an acid generator”). The acid generator is not particularly limited, but is preferably a compound that generates an organic acid upon irradiation with actinic rays or radiation.

The acid generator may be appropriately selected from known compounds that generate an acid upon irradiation with actinic rays or radiation which are used for a photo-initiator for cationic photopolymerization, a photo-initiator for radical photopolymerization, a photo-decoloring agent for dyes, a photo-discoloring agent, a microresist or the like, and a mixture thereof, and used. Examples thereof include the compounds described in paragraphs <0039> to <0103> of JP2010-61043A, the compounds described in paragraphs <0284> to <0389> of JP2013-4820A, and the like, but the present invention is not limited thereto.

Examples of such an acid generator include a diazonium salt, a phosphonium salt, a sulfonium salt, an iodonium salt, imide sulfonate, oxime sulfonate, diazodisulfone, disulfone, and o-nitrobenzyl sulfonate.

Suitable examples of the acid generator contained in the composition of the present invention include a compound (specific acid generator) that generates an acid upon irradiation with actinic rays or radiation represented by General Formula (3).

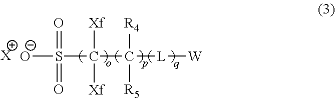

(Anion)

In General Formula (3),

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where R₄ and R₅ are present in plural numbers, they may be the same as or different from each other.

L represents a divalent linking group, and in a case where L's are present in plural numbers, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The number of carbon atoms of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. It is particularly preferable that both Xf's are fluorine atoms.

R₄ and R₅ each independently represent a hydrogen atom, a fluorine atom, an alkyl group, or an alkyl group substituted with at least one fluorine atom, and in a case where R₄ and R₅ are present in plural numbers, they may be the same as or different from each other.

The alkyl group as R₄ and R₅ may have a substituent, and preferably has 1 to 4 carbon atoms. R₄ and R₅ are each preferably a hydrogen atom.

Specific examples and suitable aspects of the alkyl group substituted with at least one fluorine atom are the same as the specific examples and suitable aspects of Xf in General Formula (3).

L represents a divalent linking group, and in a case where L's are present in plural numbers, they may be the same as or different from each other.

Examples of the divalent linking group include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

W represents an organic group including a cyclic structure. Above all, it is preferably a cyclic organic group.

Examples of the cyclic organic group include an alicyclic group, an aryl group, and a heterocyclic group.

The alicyclic group may be monocyclic or polycyclic, and examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, an alicyclic group having a bulky structure having 7 or more carbon atoms, such as a norbornyl group, a tricyclodecanyl group, a tetracyclodecanyl group, a tetracyclododecanyl group, and an adamantyl group is preferable from the viewpoints of suppressing diffusivity into the film during post exposure baking (PEB) process and improving Mask Error Enhancement Factor (MEEF).

The aryl group may be monocyclic or polycyclic. Examples of the aryl group include a phenyl group, a naphthyl group, a phenanthryl group, and an anthryl group. Among these, a naphthyl group showing a relatively low light absorbance at 193 nm is preferable.

The heterocyclic group may be monocyclic or polycyclic, but is preferably polycyclic so as to suppress acid diffusion. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle having no aromaticity include a tetrahydropyran ring, a lactone ring, a sultone ring, and a decahydroisoquinoline ring. As a heterocycle in the heterocyclic group, a furan ring, a thiophene ring, a pyridine ring, or a decahydroisoquinoline ring is particularly preferable. Further, examples of the lactone ring and the sultone ring include the lactone structures and sultone structures exemplified in the above-mentioned resin (P).

The cyclic organic group may have a substituent. Examples of the substituent include, an alkyl group (which may be linear or branched, and preferably has 1 to 12 carbon atoms), a cycloalkyl group (which may be monocyclic, polycyclic, or spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be carbonyl carbon.

o represents an integer of 1 to 3. p represents an integer of 0 to 10. q represents an integer of 0 to 10.

In one aspect, it is preferable that in General Formula (3), o is an integer of 1 to 3, p is an integer of 1 to 10, and q is 0. Xf is preferably a fluorine atom, R₄ and R₅ are preferably both hydrogen atoms, and W is preferably a polycyclic hydrocarbon group. o is more preferably 1 or 2, and still more preferably 1. p is more preferably an integer of 1 to 3, still more preferably 1 or 2, and particularly preferably 1. W is more preferably a polycyclic cycloalkyl group, and still more preferably an adamantyl group or a diadamantyl group.

(Cation)

In General Formula (3), X⁺ represents a cation.

X⁺ is not particularly limited as long as it is a cation, but suitable aspects thereof include cations (parts other than Z) in General Formula (ZI), (ZII), or (ZIII) which will be described later.

(Suitable Aspects)

Suitable aspects of the specific acid generator include a compound represented by General Formula (ZI), (ZII), or (ZIII).

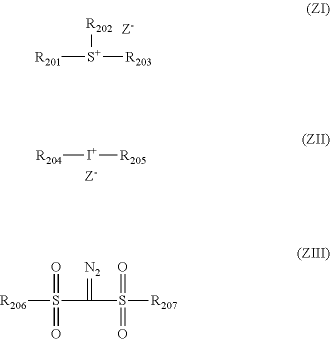

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two members out of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two members out of R₂₀₁ to R₂₀₃ include an alkylene group (for example, a butylene group and a pentylene group).

Z⁻ represents an anion in General Formula (3), and specifically represents the following anion.

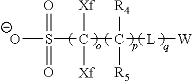

Examples of the organic group represented by R₂₀₁, R₂₀₂, and R₂₀₃ include groups corresponding to the compound (ZI-4) which will be described later.

Incidentally, it may be a compound having a plurality of structures represented by General Formula (ZI). For example, it may be a compound having a structure in which at least one of R₂₀₁, . . . , or R₂₀₃ in the compound represented by General Formula (ZI) is bonded to at least one of R₂₀₁, . . . , or R₂₀₃ of another compound represented by General Formula (ZI) through a single bond or a linking group.

More preferred examples of the component (ZI) include a compound (ZI-4) described below.

The compound (ZI-4) is represented by General Formula (ZI-4).

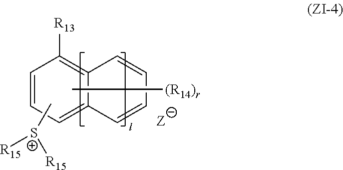

In General Formula (ZI-4),

R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where R₁₄'s are present in plural numbers, they each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

R₁₅'s each independently represent an alkyl group, a cycloalkyl group, or a naphthyl group. These groups may have a substituent. Two R₁₅'s may be bonded to each other to form a ring. When two R₁₅'s are bonded to each other to form a ring, the ring skeleton may include a heteroatom such as an oxygen atom and a nitrogen atom. In one aspect, it is preferable that two R₁₅'s are alkylene groups, and are bonded to each other to form a ring structure.

l represents an integer of 0 to 2.

r represents an integer of 0 to 8.

Z⁻ represents an anion in General Formula (3), and specifically, is as described above.

In General Formula (ZI-4), as the alkyl group of R₁₃, R₁₄, and R₁₅, an alkyl which is linear or branched and has 1 to 10 carbon atoms is preferable, and preferred examples thereof include a methyl group, an ethyl group, an n-butyl group, and a t-butyl group.

Examples of the cation of the compound represented by General Formula (ZI-4) in the present invention include the cations described in paragraphs <0121>, <0123>, and <0124> of JP2010-256842A, paragraphs <0127>, <0129>, and <0130> of JP2011-76056A, and the like.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure containing an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group in R₂₀₄ to R₂₀₇ include linear or branched alkyl groups having 1 to 10 carbon atoms (for example, a methyl group, an ethyl group, a propyl group, a butyl group, and a pentyl group), and cycloalkyl groups having 3 to 10 carbon atoms (a cyclopentyl group, a cyclohexyl group, and a norbornyl group).

The aryl group, the alkyl group, or the cycloalkyl group of R₂₀₄ to R₂₀₇ may have a substituent. Examples of the substituent which the aryl group, the alkyl group, or the cycloalkyl group of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents an anion in General Formula (3), and specifically, is as described above.

The acid generator (including a specific acid generator, which applies hereinafter) may be in a form of a low-molecular-weight compound or in a form introduced into a part of a polymer. Further, a combination of the form of a low-molecular-weight compound and the form introduced into a part of a polymer may also be used.

In a case where the acid generator is in the form of a low-molecular-weight compound, the molecular weight is preferably 3,000 or less, more preferably 2,000 or less, and still more preferably 1,000 or less.

In a case where the acid generator is in the form introduced into a part of a polymer, it may be introduced into a part of the resin P described above or into a resin other than the resin P.

The acid generator can be synthesized by a known method, and can be synthesized by, for example, the method described in JP2007-161707A.

The acid generators may be used singly or in combination of two or more kinds thereof.

The content of the acid generator (a total sum of contents in a case where the acid generators are present in plural kinds) in the composition is preferably 0.1% to 30% by mass, more preferably 0.5% to 25% by mass, still more preferably 3% to 20% by mass, and particularly preferably 3% to 15% by mass, with respect to the total solid contents of the composition.

Furthermore, the content of the acid generator (a total sum of contents in a case where the acid generators are present in plural kinds) in a case where the acid generator is a specific acid generator represented by General Formula (ZI-4) is preferably 5% to 35% by mass, more preferably 8% to 30% by mass, still more preferably 9% to 30% by mass, and particularly preferably 9% to 25% by mass, with respect to the total solid contents of the composition.

[3] Hydrophobic Resin

The composition of the present invention may contain a hydrophobic resin (hereinafter also referred to as a “hydrophobic resin (D)” or simply a “resin (D)”). Further, the hydrophobic resin (D) is preferably different from the resin P.

Although the hydrophobic resin (D) is preferably designed to be unevenly distributed on an interface as described above, it does not necessarily have to have a hydrophilic group in its molecule as different from the surfactant, and does not need to contribute to uniform mixing of polar/nonpolar materials.

Examples of the effect of addition of the hydrophobic resin include control of the static/dynamic contact angle of the resist film surface with respect to water, improvement of the immersion liquid tracking properties, and suppression of out gas.

The hydrophobic resin (D) preferably has at least one of a “fluorine atom”, a “silicon atom”, or a “CH₃ partial structure which is contained in a side chain moiety of a resin” from the viewpoint of uneven distribution on the film surface layer, and more preferably has two or more kinds.

In a case where hydrophobic resin (D) includes a fluorine atom and/or a silicon atom, the fluorine atom and/or the silicon atom in the hydrophobic resin (D) may be contained in the main chain or the side chain of the resin.

In a case where the hydrophobic resin (D) contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom and the aryl group having a fluorine atom are a cycloalkyl group in which one hydrogen atom is substituted with a fluorine atom, and an aryl group having a fluorine atom, respectively, and may further have a substituent other than a fluorine atom.

Preferred examples of the alkyl group having a fluorine atom, the cycloalkyl group having a fluorine atom, and the aryl group having a fluorine atom include groups represented by General Formulae (F2) to (F4), but the present invention is not limited thereto.

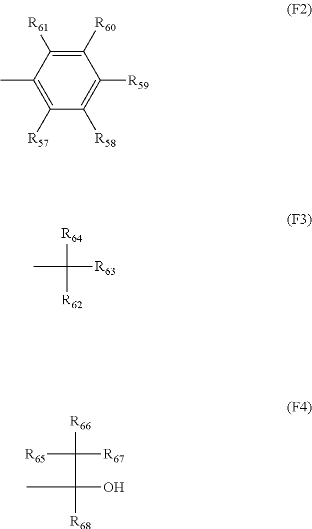

In General Formulae (F2) to (F4),

R₅₇ to R₆₈ each independently represent a hydrogen atom, a fluorine atom, or an (linear or branched) alkyl group, a provided that at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

The hydrophobic resin (D) may contain a silicon atom. It is preferably a resin having, as the partial structure having a silicon atom, an alkylsilyl structure (preferably a trialkylsilyl group) or a cyclic siloxane structure.

Examples of the repeating unit having a fluorine atom or a silicon atom include those exemplified in [0519] of US2012/0251948A1.

Moreover, it is also preferable that the hydrophobic resin (D) contains a CH₃ partial structure in the side chain moiety as described above.

Here, the CH₃ partial structure (hereinafter also simply referred to as a “side chain CH₃ partial structure”) contained in the side chain moiety in the hydrophobic resin (D) includes a CH₃ partial structure contained in an ethyl group, a propyl group, and the like.

On the other hand, a methyl group bonded directly to the main chain of the hydrophobic resin (D) (for example, an α-methyl group in the repeating unit having a methacrylic acid structure) makes only a small contribution of uneven distribution to the surface of the hydrophobic resin (D) due to the effect of the main chain, and it is therefore not included in the side chain CH₃ partial structure in the present invention.

More specifically, in a case where the hydrophobic resin (D) contains a repeating unit derived from a monomer having a polymerizable moiety with a carbon-carbon double bond, such as a repeating unit represented by General Formula (M), and in addition, R₁₁ to R₁₄ are CH₃ “themselves”, such CH₃ is not included in the side chain CH₃ partial structure contained in the side chain moiety in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the hydrophobic resin has “one” side chain CH₃ partial structure in the present invention.

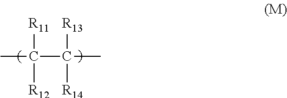

In General Formula (M),

R₁₁ to R₁₄ each independently represent a side chain moiety.

Examples of R₁₁ to R₁₄ at the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The hydrophobic resin (D) is preferably a resin including a repeating unit having the CH₃ partial structure in the side chain moiety thereof. Further, the hydrophobic resin more preferably has, as such a repeating unit, at least one repeating unit (x) selected from a repeating unit represented by General Formula (II) or a repeating unit represented by General Formula (III).

Hereinafter, the repeating unit represented by General Formula (II) will be described in detail.

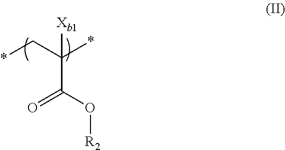

In General Formula (II), X_{b1} represents a hydrogen atom, an alkyl group, a cyano group, or a halogen atom, and R₂ represents an organic group which has one or more CH₃ partial structures and is stable against an acid. Here, it is preferable that the organic group which is stable against an acid is more specifically an organic group having no acid-decomposable group (group that decomposes by the action of an acid to generate a polar group such as a carboxyl group).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably 2 to 10, and more preferably 2 to 8.

Specific preferred examples of the repeating unit represented by General Formula (II) are shown below, but the present invention is not limited thereto.

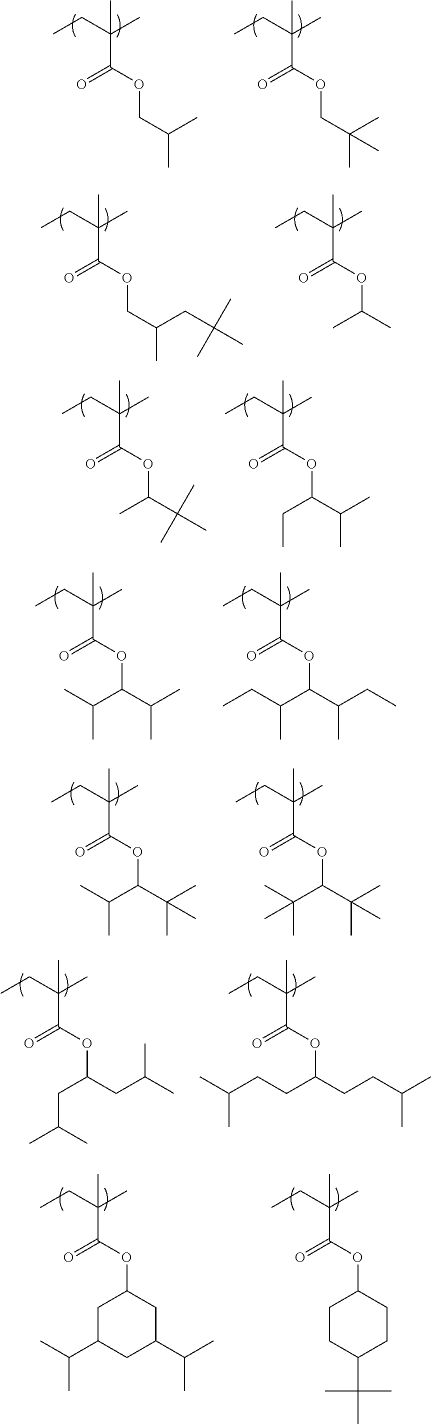

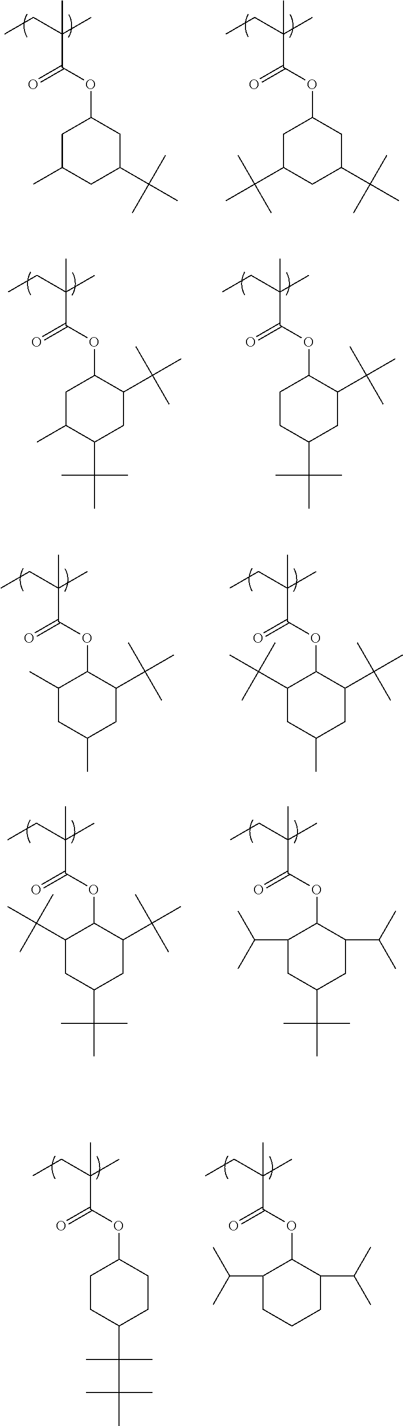

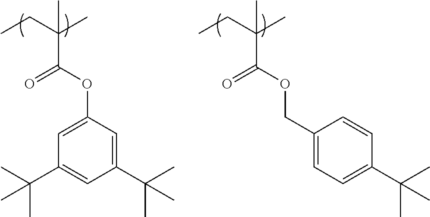

The repeating unit represented by General Formula (II) is preferably a repeating unit which is stable against an acid (acid-indecomposable), and specifically, it is preferably a repeating unit not having a group that decomposes by the action of an acid to generate a polar group.

Hereinafter, the repeating unit represented by General Formula (III) will be described in detail.

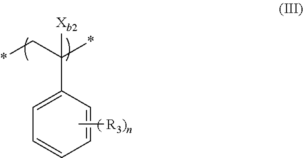

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, it is preferable that R₃ is more specifically an organic group having no acid-decomposable group.

Examples of R₃ include an alkyl group having one or more CH₃ partial structures.

The number of the CH₃ partial structures contained in the organic group which has one or more CH₃ partial structures and is stable against an acid as R₃ is preferably 1 to 10, more preferably 1 to 8, and still more preferably 1 to 4.

n represents an integer of 1 to 5, more preferably 1 to 3, and still more preferably 1 or 2.

Specific preferred examples of the repeating unit represented by General Formula (III) are shown below, but the present invention is not limited thereto.

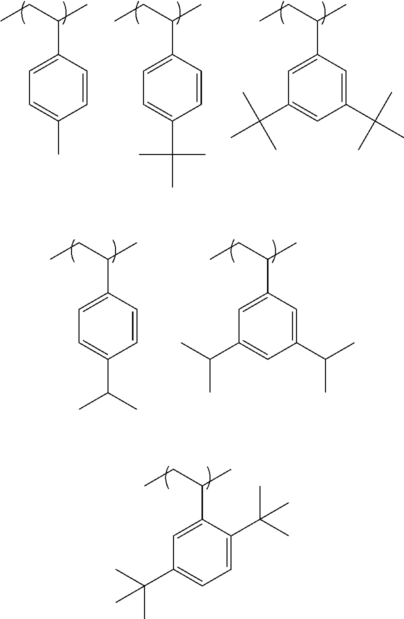

The repeating unit represented by General Formula (III) is preferably a repeating unit which is stable against an acid (acid-indecomposable), and specifically, it is preferably a repeating unit which does not have a group that decomposes by the action of an acid to generate a polar group.

In a case where the hydrophobic resin (D) includes a CH₃ partial structure in the side chain moiety thereof, and in particular, it has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the hydrophobic resin (D). Further, the content is usually 100% by mole or less with respect to all the repeating units of the hydrophobic resin (D).

By incorporating at least one repeating unit (x) of the repeating unit represented by General Formula (II) or the repeating unit represented by General Formula (III) in a proportion of 90% by mole or more with respect to all the repeating units of the hydrophobic resin (D) into the hydrophobic resin (D), the surface free energy of the hydrophobic resin (D) is increased. As a result, it is difficult for the hydrophobic resin (D) to be unevenly distributed on the surface of the resist film and the static/dynamic contact angle of the resist film with respect to water can be securely increased, thereby enhancing the immersion liquid tracking properties.

In addition, in a case where the hydrophobic resin (D) contains (i) a fluorine atom and/or a silicon atom or (ii) a CH₃ partial structure in the side chain moiety, the hydrophobic resin may have at least one group selected from the following groups (x) to (z):

(x) an acid group,

(y) a group having a lactone structure, an acid anhydride group, or an acid imido group, and

(z) a group that decomposes by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the acid group include a fluorinated alcohol group (preferably a hexafluoroisopropanol group), a sulfonimido group, and a bis(alkylcarbonyl)methylene group.

Examples of the repeating unit containing an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization. All of these cases are preferable. The repeating unit having an acid group (x) may have at least one of a fluorine atom or a silicon atom.

The content of the repeating units containing an acid group (x) is preferably 1% to 50% by mole, more preferably 3% to 35% by mole, and still more preferably 5% to 20% by mole, with respect to all the repeating units in the hydrophobic resin (D).

Specific examples of the repeating unit having an acid group (x) are shown below, but the present invention is not limited thereto. In the formulae, Rx represents a hydrogen atom, CH₃, CF₃, or CH₂OH.

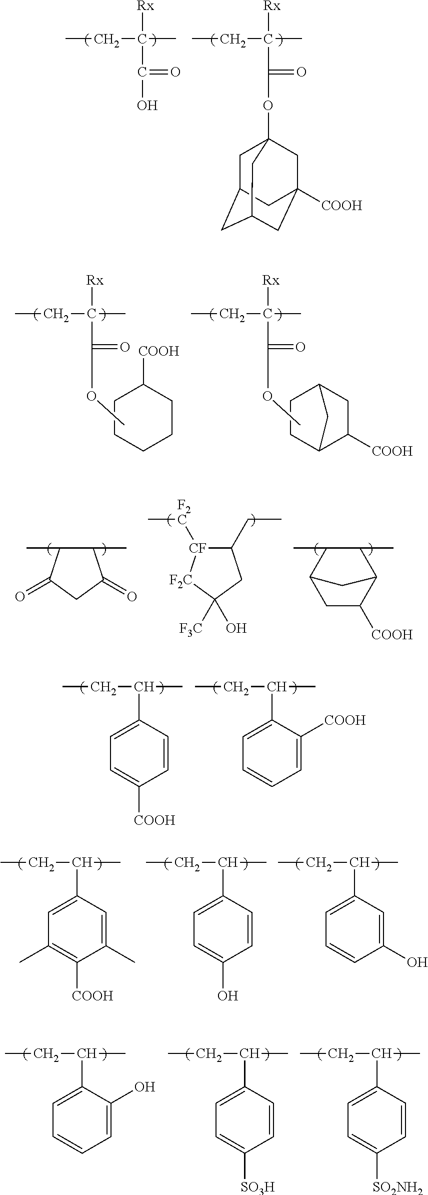

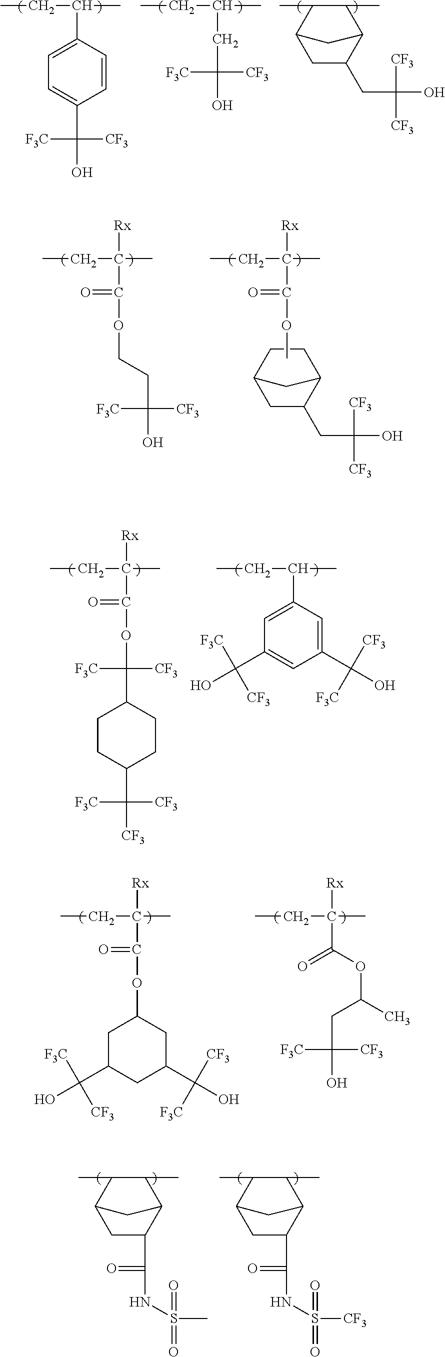

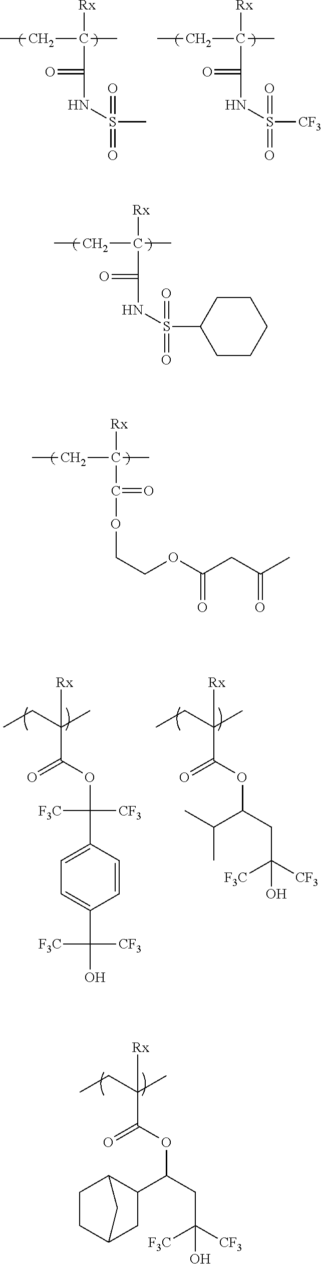

As the group having a lactone structure, the acid anhydride group, or the acid imido group (y), a group having a lactone structure is particularly preferable.

The repeating unit including such a group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively this repeating unit may be introduced into the terminal of the resin by using a polymerization initiator or chain transfer agent containing the group during the polymerization.

Examples of the repeating unit containing a group having a lactone structure include the same ones as the repeating unit having a lactone structure as described earlier in the section of the resin P.

The content of the repeating units having a group having a lactone structure, an acid anhydride group, or an acid imido group is preferably 1% to 100% by mole, more preferably 3% to 98% by mole, and still more preferably 5% to 95% by mole, with respect to all the repeating units in the hydrophobic resin (D).

With respect to the hydrophobic resin (D), examples of the repeating unit having a group (z) that decomposes by the action of an acid include the same ones as the repeating units having an acid-decomposable group, as mentioned with respect to the resin P. The repeating unit having a group (z) that decomposes by the action of an acid may have at least one of a fluorine atom or a silicon atom. With respect to the hydrophobic resin (D), the content of the repeating units having a group (z) that decomposes by the action of an acid is preferably 1% to 80% by mole, more preferably 10% to 80% by mole, and still more preferably 20% to 60% by mole, with respect to all the repeating units in the resin (D).

The hydrophobic resin (D) may further have repeating units different from the above-mentioned repeating units.

The content of the repeating units including a fluorine atom is preferably 10% to 100% by mole, and more preferably 30% to 100% by mole, with respect to all the repeating units included in the hydrophobic resin (D). Further, the content of the repeating units including a silicon atom is preferably 10% to 100% by mole, and more preferably 20% to 100% by mole, with respect to all the repeating units included in the hydrophobic resin (D).

On the other hand, in particular, in a case where the hydrophobic resin (D) includes a CH₃ partial structure in the side chain moiety thereof, it is also preferable that the hydrophobic resin (D) has a form not having substantially any one of a fluorine atom and a silicon atom. Further, it is preferable that the hydrophobic resin (D) is substantially composed of only repeating units, which are composed of only atoms selected from a carbon atom, an oxygen atom, a hydrogen atom, a nitrogen atom, and a sulfur atom.

The weight-average molecular weight of the hydrophobic resin (D) in terms of standard polystyrene is preferably 1,000 to 100,000, and more preferably 1,000 to 50,000.

Furthermore, the hydrophobic resins (D) may be used singly or in combination of plural kinds thereof.

The content of the hydrophobic resin (D) in the composition is preferably 0.01% to 10% by mass, and more preferably 0.05% to 8% by mass, with respect to the total solid contents of the composition of the present invention.

In the hydrophobic resin (D), the content of residual monomers or oligomer components is also preferably 0.01% to 5% by mass, and more preferably 0.01% to 3% by mass. Further, the molecular weight distribution (Mw/Mn, also referred to as a dispersity) is preferably in the range of 1 to 5, and more preferably in the range of 1 to 3.

As the hydrophobic resin (D), various commercial products may also be used, or the resin may be synthesized by an ordinary method (for example, radical polymerization).

[4] Acid Diffusion Control Agent

The composition of the present invention preferably contains an acid diffusion control agent. The acid diffusion control agent acts as a quencher that inhibits a reaction of the acid-decomposable resin in the unexposed area by excessive generated acids by trapping the acids generated from an acid generator or the like upon exposure. As the acid diffusion control agent, a basic compound, a low-molecular-weight compound which has a nitrogen atom and a group that leaves by the action of an acid, or an onium salt which becomes a relatively weak acid relative to the acid generator can be used.

Preferred examples of the basic compound include compounds having structures represented by the following Formulae (A) to (E).

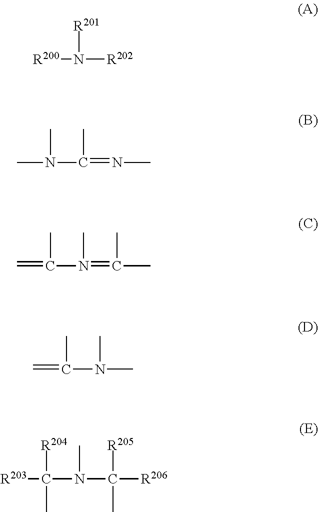

In General Formulae (A) and (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and R²⁰¹ and R²⁰² may be bonded to each other to form a ring.

R²⁰³, R²⁰⁴, R²⁰⁵, and R²⁰⁶ may be the same as or different from each other, and each represent an alkyl group having 1 to 20 carbon atoms.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in General Formulae (A) and (E) are more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Specific preferred examples of the compound include the compounds exemplified in paragraph <0379> in the specification of US2012/0219913A1.

Preferred examples of the basic compound include an amine compound having a phenoxy group, an ammonium salt compound having a phenoxy group, an amine compound containing a sulfonic ester group, and an ammonium salt compound having a sulfonic ester group.

These basic compounds may be used singly or in combination of two or more kinds thereof.

The composition of the present invention may or may not contain the basic compound, but in a case where it contains the basic compound, the content of the basic compound is usually 0.001% to 10% by mass, and preferably 0.01% to 5% by mass, with respect to the solid content of the composition.

The ratio between the acid generator to the basic compound to be used in the composition, in terms of a molar ratio (acid generator/basic compound), is preferably 2.5 to 300, more preferably 5.0 to 200, and still more preferably 7.0 to 150.

The low-molecular-weight compound (hereinafter referred to as a “compound (C)”) which has a nitrogen atom and a group that leaves by the action of an acid is preferably an amine derivative having a group that leaves by the action of an acid on a nitrogen atom.

As the group that leaves by the action of an acid, an acetal group, a carbonate group, a carbamate group, a tertiary ester group, a tertiary hydroxyl group, or a hemiaminal ether group are preferable, and a carbamate group or a hemiaminal ether group is particularly preferable.

The molecular weight of the compound (C) is preferably 100 to 1,000, more preferably 100 to 700, and particularly preferably 100 to 500.

The compound (C) may have a carbamate group having a protecting group on a nitrogen atom. The protecting group constituting the carbamate group can be represented by General Formula (d-1).

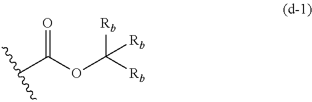

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be substituted with a functional group such as a hydroxyl group, a cyano group, an amino group, a pyrrolidino group, a piperidino group, a morpholino group, and an oxo group, an alkoxy group, or a halogen atom. This shall apply to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in paragraph <0466> in the specification of US2012/0135348A1.

It is particularly preferable that the compound (C) has a structure of General Formula (6).

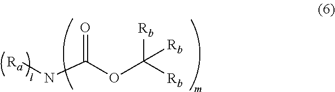

In General Formula (6), Rₐ represents a hydrogen atom, an alkyl group, a cycloalkyl group, an aryl group, or an aralkyl group. When 1 is 2, two Rₐ's may be the same as or different from each other. Two Rₐ's may be linked to each other to form a heterocycle may be bonded to each other to form, together with a carbon atom to which they are bonded with the nitrogen atom in the formula. The heterocycle may contain a heteroatom other than the nitrogen atom in the formula.

R_{b} has the same meaning as R_{b} in General Formula (d-1), and preferred examples are also the same.

l represents an integer of 0 to 2, and m represents an integer of 1 to 3, satisfying l+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, a cycloalkyl group, an aryl group, and an aralkyl group may be substituted with the groups as described above) of Rₐ include the same groups as the specific examples as described above with respect to R_{b}.

Specific examples of the particularly preferred compound (C) in the present invention include, but are not limited to, the compounds disclosed in paragraph <0475> in the specification of US2012/0135348A1.

The compounds represented by General Formula (6) can be synthesized in accordance with JP2007-298569A, JP2009-199021A, and the like.

In the present invention, the low-molecular-weight compound (C) having a group that leaves by the action of an acid on a nitrogen atom may be used singly or in combination of two or more kinds thereof.

The content of the compound (C) in the composition of the present invention is preferably 0.001% to 20% by mass, more preferably 0.001% to 10% by mass, and still more preferably 0.01% to 5% by mass, with respect to the total solid contents of the composition.

In the composition of the present invention, an onium salt which becomes a relatively weak acid with respect to the acid generator can be used as an acid diffusion control agent.

In a case of mixing the acid generator and the onium salt that generates an acid which is a relatively weak acid with respect to an acid generated from the acid generator, and then using the mixture, when the acid generated from the acid generator upon irradiation with actinic rays or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which becomes a relatively weak acid with respect to the acid generator, compounds represented by General Formulae (d1-1) to (d1-3) are preferable.

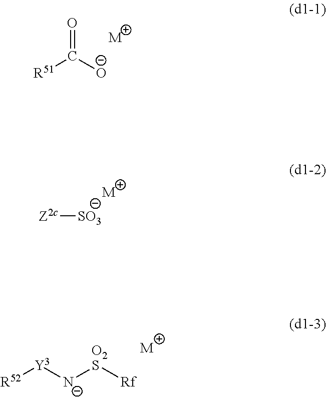

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent, R⁵² is an organic group, Y³ is a linear, branched, or cyclic alkylene group or arylene group, Rf is a hydrocarbon group containing a fluorine atom, and M⁺'s are each independently a sulfonium or iodonium cation.

Preferred examples of the sulfonium cation or the iodonium cation represented by M⁺ include the sulfonium cations exemplified by General Formula (ZI) and the iodonium cations exemplified by General Formula (ZII).

Preferred examples of the anionic moiety of the compound represented by General Formula (d1-1) include the structures exemplified in paragraph [0198] of JP2012-242799A.

Preferred examples of the anionic moiety of the compound represented by General Formula (d1-2) include the structures exemplified in paragraph [0201] of JP2012-242799A.

Preferred examples of the anionic moiety of the compound represented by General Formula (d1-3) include the structures exemplified in paragraphs [0209] and [0210] of JP2012-242799A.

The onium salt which becomes a relatively weak acid with respect to the acid generator may be a compound (hereinafter also referred to as a “compound (CA)”) having a cationic moiety (C) and an anionic moiety in the same molecule, in which the cationic moiety and the anionic moiety are linked to each other through a covalent bond.

As the compound (CA), a compound represented by any one of General Formulae (C-1) to (C-3) is preferable.

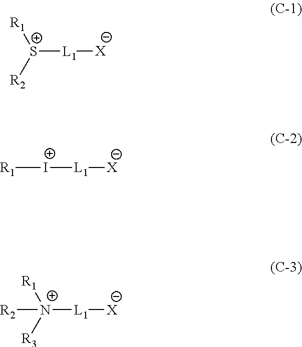

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to one another to form a ring structure. Further, in (C-3), two members out of R₁ to R₃ may be combined to form a double bond with an N atom.

Examples of the substituent having 1 or more carbon atoms in R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and preferably an alkyl group, a cycloalkyl group, and an aryl group.

Examples of L₁ as a divalent linking group include a linear or branched alkylene group, a cycloalkylene group, an arylene group, a carbonyl group, an ether bond, ester bond, amide bond, a urethane bond, a urea bond, and a group formed by a combination of two or more kinds of these groups. L₁ is more preferably an alkylene group, an arylene group, an ether bond, ester bond, and a group formed by a combination of two or more kinds of these groups.

Preferred examples of the compound represented by General Formula (C-1) include the compounds exemplified in paragraphs [0037] to [0039] of JP2013-6827A and paragraphs [0027] to [0029] of JP2013-8020A.

Preferred examples of the compound represented by General Formula (C-2) include the compounds exemplified in paragraphs [0012] to [0013] of JP2012-189977A.

Preferred examples of the compound represented by General Formula (C-3) include the compounds exemplified in paragraphs [0029] to [0031] of JP2012-252124A.

The content of the onium salt which becomes a relatively weak acid with respect to the acid generator is preferably 0.5% to 10.0% by mass, more preferably 0.5% to 8.0% by mass, and still more preferably 1.0% to 8.0% by mass, with respect to the solid content of the composition.

[5] Solvent

The composition of the present invention usually contains a solvent.

Examples of the solvent which can be used in the preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include the solvents described in <0441> to <0455> in the specification of US2008/0187860A.

In the present invention, a mixed solvent obtained by mixing a solvent containing a hydroxyl group and a solvent containing no hydroxyl group in the structure may be used as the organic solvent.

As the solvent containing a hydroxyl group and the solvent containing no hydroxyl group, the aforementioned exemplary compounds can be appropriately selected, but as the solvent containing a hydroxyl group, an alkylene glycol monoalkyl ether, alkyl lactate, and the like are preferable, and propylene glycol monomethyl ether (PGME, alternative name: 1-methoxy-2-propanol), methyl 2-hydroxyisobutyrate, and ethyl lactate are more preferable. Further, as the solvent containing no hydroxyl group, alkylene glycol monoalkyl ether acetate, alkyl alkoxy propionate, a monoketone compound which may contain a ring, cyclic lactone, alkyl acetate, and the like are preferable. Among these, propylene glycol monomethyl ether acetate (PGMEA, alternative name: 1-methoxy-2-acetoxypropane), ethyl ethoxypropionate, 2-heptanone, γ-butyrolactone, cyclohexanone, and butyl acetate are particularly preferable, and propylene glycol monomethyl ether acetate, ethyl ethoxypropionate, and 2-heptanone are most preferable.

The mixing ratio (mass ratio) of the solvent containing a hydroxyl group to the solvent containing no hydroxyl group is 1/99 to 99/1, preferably 10/90 to 90/10, and more preferably 20/80 to 60/40. A mixed solvent whose proportion of the solvent containing no hydroxyl group is 50% by mass or more is particularly preferable from the viewpoint of coating evenness.

The solvent preferably contains propylene glycol monomethyl ether acetate, and is preferably a solvent composed of propylene glycol monomethyl ether acetate singly or a mixed solvent of two or more kinds of solvents including propylene glycol monomethyl ether acetate.

[6] Surfactant

The composition of the present invention may or may not further contain a surfactant. In a case where the composition contains the surfactant, it is more preferable that the composition contains any one of fluorine- and/or silicon-based surfactants (a fluorine-based surfactant, a silicon-based surfactant, and a surfactant having both a fluorine atom and a silicon atom).

By incorporating the surfactant into the composition of the present invention, it becomes possible to provide a resist pattern having improved adhesiveness and decreased development defects with good sensitivity and resolution when an exposure light source of 250 nm or less, and particularly 220 nm or less, is used.

Examples of the fluorine- and/or silicon-based surfactants include the surfactants described in paragraph <0276> in the specification of US2008/0248425A.

In addition, in the present invention, surfactants other than the fluorine- and/or silicon-based surfactants described in paragraph <0280> in the specification of US2008/0248425A can also be used.

These surfactants may be used singly or in combination of a few surfactants.

In a case where the composition of the present invention contains a surfactant, the content of the surfactant is preferably 0.0001% to 2% by mass, and more preferably 0.0005% to 1% by mass, with respect to the total solid contents of the composition.

On the other hand, by setting the amount of the surfactant to be added to 10 ppm or less with respect to the total amount (excluding the solvent) of the composition, the hydrophobic resin is more unevenly distributed to the surface, so that the resist film surface can be made more hydrophobic, which can enhance the water tracking properties during the liquid immersion exposure.

[7] Other Additives

The composition of the present invention may or may not contain an onium carboxylate salt. Examples of such an onium carboxylate salt include those described in <0605> to <0606> in the specification of US2008/0187860A.

The onium carboxylate salt can be synthesized by reacting sulfonium hydroxide, iodonium hydroxide, ammonium hydroxide and carboxylic acid with silver oxide in a suitable solvent.

In a case where the composition of the present invention contains the onium carboxylate salt, the content of the salt is generally 0.1% to 20% by mass, preferably 0.5% to 10% by mass, and more preferably 1% to 7% by mass, with respect to the total solid contents of the composition.

The composition of the present invention may further contain an acid proliferation agent, a dye, a plasticizer, a light sensitizer, a light absorbent, an alkali-soluble resin, a dissolution inhibitor, a compound promoting solubility in a developer (for example, a phenol compound with a molecular weight of 1,000 or less, an alicyclic or aliphatic compound having a carboxyl group), and the like, as desired.

Such a phenol compound having a molecular weight of 1,000 or less can be easily synthesized by those skilled in the art with reference to the method described in, for example, JP1992-122938A (JP-H04-122938A), JP1990-28531A (JP-H02-28531A), U.S. Pat. No. 4,916,210A, EP219294B, or the like.

Specific examples of the alicyclic compound or aliphatic compound having a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The composition of the present invention is preferably a resist film having a film thickness of 80 nm or less from the viewpoint of improving the resolving power. It is possible to set the film thickness by setting the concentration of the solid content in the composition to an appropriate range, thus to have a suitable viscosity and improve a coating property and a film forming property.

The concentration of the solid content of the composition according to the present invention is usually 1.0% to 10% by mass, preferably 2.0% to 5.7% by mass, and more preferably 2.0% to 5.3% by mass. By setting the concentration of the solid content to these ranges, it is possible to uniformly coat the resist solution on a substrate and additionally, it is possible to form a resist pattern having excellent line width roughness. The reason is not clear; however, it is considered that, by setting the concentration of the solid content to 10% by mass or less, and preferably 5.7% by mass or less, the aggregation of materials, particularly the photoacid generator, in the resist solution is suppressed and, as the result, it is possible to form a uniform resist film.

The concentration of the solid content is the mass percentage of the mass of other resist components excluding the solvent with respect to the total mass of the composition.

The composition of the present invention is used by dissolving the components in a predetermined organic solvent, and preferably in the mixed solvent, filtering the solution through a filter, and then applying the filtered solution on a predetermined support (substrate). The filter for use in filtration is preferably a polytetrafluoroethylene-, polyethylene- or nylon-made filter having a pore size of 0.1 μm or less, more preferably 0.05 μm or less, and still more preferably 0.03 μm or less. In the filtration through a filter, as described in, for example, JP2002-62667A, circulating filtration may be carried out, or the filtration may be carried out by connecting plural kinds of filters in series or in parallel. In addition, the composition may be filtered in plural times. Furthermore, the composition may be subjected to a deaeration treatment or the like before or after filtration through a filter.

The composition of the present invention is related to an actinic ray-sensitive or radiation-sensitive resin composition whose properties change by undergoing a reaction upon irradiation with active rays or radiation. More specifically, the present invention relates to an actinic ray-sensitive or radiation-sensitive resin composition which can be used in for a step of manufacturing a semiconductor such as an IC, for manufacture of a circuit board for a liquid crystal, a thermal head, or the like, the manufacture of a mold structure for imprinting, or a other photofabrication processes, or used in a planographic printing plate or an acid-curable composition.

[Pattern Forming Method]

Next, the pattern forming method of the present invention will be described.

The pattern forming method of the present invention includes at least the following steps:

(i) a step of forming a film (an actinic ray-sensitive or radiation-sensitive resin composition film, a composition film, or a resist film) on a substrate, using the composition of the present invention,

(ii) a step of irradiating (exposing) the film with actinic rays or radiation (exposing step), and

(iii) a step of developing the film irradiated with actinic rays or radiation, using a developer containing an organic solvent (developing step).

The exposure in the step (ii) may be liquid immersion exposure.

It is preferable that the pattern forming method of the present invention includes (iv) a heating step after (ii) the exposing step.

The pattern forming method of the present invention may include (ii) the exposing step in plural times.

The pattern forming method of the present invention may include (iv) the heating step in plural times.

The resist film in the present invention is a film formed from the aforementioned composition of the present invention, and more specifically, it is preferably a film formed by applying the composition onto a substrate. In the pattern forming method of the present invention, the step of forming a film from the composition on a substrate, the step of exposing the film, and the developing step can be carried out by generally known methods.

The substrate on which the film is formed in the present invention is not particularly limited, and a substrate generally used in a process for manufacturing a semiconductor such as an IC, and a process for manufacture of a circuit board for a liquid crystal, a thermal head, or the like; and in other lithographic processes of photofabrication can be used. Specific examples of the substrate include an inorganic substrate such as silicone, SiO₂, and SiN; and a coating type inorganic substrate such as Spin On Glass (SOG).

In addition, an antireflection film may further be formed between the resist film and the substrate, as desired. As the antireflection film, a known organic or inorganic antireflection film can be appropriately used.

It is also preferable that the method includes a pre-heating step (PB; Prebake) after forming a film and before the exposing step.

Moreover, it is also preferable that the method includes a step of heating after exposure (PEB: Post Exposure Bake) after the exposing step and before the developing step.

For both of PB and PEB, the heating is preferably carried out at a heating temperature of 70° C. to 130° C., and more preferably 80° C. to 120° C.

The heating time is preferably 30 to 300 seconds, more preferably 30 to 180 seconds, and still more preferably 30 to 90 seconds.

Heating may be carried out using a means equipped in an ordinary exposure machine and a development machine, or may also be carried out using a hot plate or the like.

The baking accelerates the reaction in the exposed areas, and thus, the sensitivity and the pattern profile are enhanced.

The light source wavelength used in the exposure device in the present invention is not particularly limited, and examples thereof include infrared rays, visible light, ultraviolet rays, far ultraviolet rays, extreme ultraviolet rays, X-rays, and electron beams, for example, far ultraviolet rays at a wavelength of preferably 250 nm or less, more preferably 220 nm or less, and particularly preferably 1 to 200 nm, specifically a KrF excimer laser (248 nm), an ArF excimer laser (193 nm), an F₂ excimer laser (157 nm), X-rays, EUV (13 nm), electron beams, and the like, with the KrF excimer laser, the ArF excimer laser, EUV, or the electron beams being preferable, and the ArF excimer laser being more preferable.

Furthermore, a liquid immersion exposure method can be applied to the step of carrying out exposure in the present invention. It is possible to combine the liquid immersion exposure method with super-resolution technology such as a phase shift method and a modified illumination method. The liquid immersion exposure can be carried out by the method described in, for example, paragraphs <0594> to <0601> of JP2013-242397A.

Moreover, if the receding contact angle of the resist film formed using the composition in the present invention is extremely small, the resist film cannot be suitably used in a case of carrying out the exposure through a liquid immersion medium. Further, the effect of reducing watermark defect cannot be sufficiently exhibited. In order to realize a favorable receding contact angle, it is preferable to incorporate the hydrophobic resin (D) into the composition. Alternatively, a film (hereinafter also referred to as a “topcoat”) sparingly soluble in an immersion liquid, which is formed of the hydrophobic resin (D), may be provided on the upper layer of the resist film. The functions required for the topcoat are coating suitability on the upper layer part of a resist film, and sparing solubility in an immersion liquid. It is preferable that the topcoat is not mixed with the composition film and can be uniformly applied onto the upper layer of a composition film.

The topcoat is not particularly limited, and topcoats known in the related art can be formed according to the methods known in the related art, and can be formed, for example, according to the description in paragraphs <0072> to <0082> of JP2014-059543A.

In a case where a developer containing an organic solvent is used in the developing step which will be described later, it is preferable that a topcoat containing the basic compound described in JP2013-61648A, for example, is formed on a resist film.

In addition, even in a case where exposure is carried out by a method other than the liquid immersion exposure method, a topcoat may be formed on a resist film.

In the liquid immersion exposure step, it is necessary for the immersion liquid to move on a wafer following the movement of an exposure head which scans the wafer at a high speed to form an exposed pattern. Therefore, the contact angle of the immersion liquid for the resist film in a dynamic state is important, and the resist is required to have a performance of allowing the immersion liquid to follow the high-speed scanning of an exposure head with no remaining of a liquid droplet.

A developer containing an organic solvent (hereinafter also referred to as an “organic developer”) can be used in the step of developing the actinic ray-sensitive or radiation-sensitive resin composition film formed using the composition of the present invention.

As the organic developer, a polar solvent such as a ketone-based solvent, an ester-based solvent, an alcohol-based solvent, an amide-based solvent, and an ether-based solvent, or a hydrocarbon-based solvent can be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, and isophorone.

Examples of the ester-based solvent include methyl acetate, butyl acetate, ethyl acetate, isopropyl acetate, pentyl acetate, isopentyl acetate, amyl acetate, isoamyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isobutyl isobutyrate, butyl propionate, and propylene carbonate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include dioxane and tetrahydrofuran, in addition to the glycol ether-based solvents above.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene; and aliphatic hydrocarbon-based solvents such as pentane, hexane, octane, and decane.

The above solvents can be used by mixing a plurality of the solvents or by mixing water or solvents other than the above solvents. However, in order to sufficiently exhibit the effects of the present invention, the moisture content in the entire developer is preferably less than 10% by mass, but a developer having substantially no water is more preferable.

That is, the content of the organic solvent with respect to the organic developer is preferably from 90% by mass to 100% by mass, and more preferably from 95% by mass to 100% by mass, with respect to the total amount of the developer.

In particular, the organic developer is preferably a developer containing at least one organic solvent selected from the group consisting of a ketone-based solvent, an ester-based solvent, an alcohol-based solvent, an amide-based solvent, and an ether-based solvent.

The vapor pressure of the organic developer at 20° C. is preferably 5 kPa or less, more preferably 3 kPa or less, and particularly preferably 2 kPa or less. By setting the vapor pressure of the organic developer to 5 kPa or less, the evaporation of the developer on the substrate or in a developing cup is suppressed, the temperature uniformity in the wafer surface is improved, and as a result, the dimensional uniformity within a wafer surface is improved.

It is possible to add an appropriate amount of a surfactant to the organic developer, as desired.

The surfactant is not particularly limited, but it is possible to use, for example, ionic or non-ionic fluorine-based and/or silicon-based surfactants, or the like. Examples of the fluorine-based and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and non-ionic surfactants are preferable. The non-ionic surfactant is not particularly limited, but it is more preferable to use a fluorine-based surfactant or a silicon-based surfactant.

The content of the surfactant is usually 0.001% to 5% by mass, preferably 0.005% to 2% by mass, and more preferably 0.01% to 0.5% by mass, with respect to the total amount of the developer.

The organic developer may include a basic compound. Specific and preferred examples of the basic compound which can be included in the organic developer are the same ones as for the basic compound which can be included in the composition of the present invention.

As the developing method, for example, a method in which a substrate is immersed in a tank filled with a developer for a certain period of time (a dip method), a method in which a developer is heaped up to the surface of a substrate by surface tension and developed by stopping for a certain period of time (a paddle method), a method in which a developer is sprayed on the surface of a substrate (a spray method), a method in which a developer is continuously discharged on a substrate spun at a constant rate while scanning a developer discharging nozzle at a constant rate (a dynamic dispense method), or the like, can be applied. Further, suitable ranges of the discharge pressure of the developer to be discharged, methods for adjusting the discharge pressure of the developer, and the like are not particularly limited, and for example, the ranges and the methods described in paragraphs <0631> to <0636> of JP2013-242397A can be used.

In the pattern forming method of the present invention, a step of performing development by using a developer containing an organic solvent (organic solvent developing step) and a step of carrying out development by using an aqueous alkali-solution (alkali developing step) may be used in combination. Due to this combination, a finer pattern can be formed.

In the present invention, an area with a low exposure intensity is removed in the organic solvent developing step, and by further carrying out the alkali developing step, an area with a high exposure intensity is also removed. By virtue of a multiple development process in which development is carried out in plural times in this way, a pattern can be formed by keeping only a region with an intermediate exposure intensity from not being dissolved, so that a finer pattern than usual can be formed (the same mechanism as in <0077> of JP2008-292975A).

It is preferable that the method includes a step of rinsing using a rinsing liquid after the step of carrying out development using a developer including an organic solvent.

The rinsing liquid used in the rinsing step after the step of carrying out development using a developer including an organic solvent is not particularly limited as long as the rinsing liquid does not dissolve the resist pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those described for the developer containing an organic solvent.

After the developing step using a developer including an organic solvent, it is more preferable to carry out a step of performing washing using a rinsing liquid containing at least one organic solvent selected from the group consisting of a ketone-based solvent, an ester-based solvent, an alcohol-based solvent, an amide-based solvent, and a hydrocarbon-based solvent, it is still more preferable to carry out a step of performing washing using a rinsing liquid containing an alcohol-based solvent or an ester-based solvent, it is particularly preferable to carry out a step of performing washing using a rinsing liquid containing a monohydric alcohol, and it is most preferable to carry out a step of performing washing using a rinsing liquid containing a monohydric alcohol having 5 or more carbon atoms.

Here, examples of the monohydric alcohol used in the rinsing step include linear, branched, or cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, or the like can be used. Further, 1-hexanol, 2-hexanol, 4-methyl-2-pentanol, 1-pentanol, 3-methyl-1-butanol, or the like can be used as a particularly preferred monohydric alcohol having 5 or more carbon atoms.

The rinsing liquid containing the hydrocarbon-based solvent is preferably a hydrocarbon compound having 6 to 30 carbon atoms, more preferably a hydrocarbon compound having 8 to 30 carbon atoms, and particularly preferably a hydrocarbon compound having 10 to 30 carbon atoms. By using a rinsing liquid including decane and/or undecane among these, pattern collapse is suppressed.

In a case of using an ester-based solvent as the rinsing liquid, a glycol ether-based solvent may be used, in addition to the ester-based solvent (one kind or two or more kinds). Specific examples of such a case include use of an ester-based solvent (preferably butyl acetate) as a main component and a glycol ether-based solvent (preferably propylene glycol monomethyl ether (PGME)) as a side component. Thus, residue defects are suppressed.

The respective components in plural numbers may be mixed, or the components may be mixed with an organic solvent other than the above solvents, and used.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure at 20° C. of the rinsing liquid which is used after the step of carrying out development using a developer including an organic solvent is preferably from 0.05 kPa to 5 kPa, more preferably from 0.1 kPa to 5 kPa, and most preferably from 0.12 kPa to 3 kPa. By setting the vapor pressure of the rinsing liquid to a range from 0.05 kPa to 5 kPa, the temperature uniformity within a wafer surface is improved, and further, the dimensional uniformity within a wafer surface is enhanced by suppression of swelling due to the permeation of the rinsing liquid.

The rinsing liquid can also be used after adding an appropriate amount of a surfactant thereto.

In the rinsing step, the wafer which has been subjected to development using a developer including an organic solvent is subjected to a washing treatment using the rinsing liquid including an organic solvent. A method for the washing treatment is not particularly limited, and for example, a method in which a rinsing liquid is continuously discharged on a substrate rotated at a constant rate (a rotation application method), a method in which a substrate is immersed in a tank filled with a rinsing liquid for a certain period of time (a dip method), a method in which a rinsing liquid is sprayed on a substrate surface (a spray method), or the like, can be applied. Among these, a method in which a washing treatment is carried out using the rotation application method, and a substrate is rotated at a rotation speed of 2,000 rpm to 4,000 rpm after washing, thereby removing the rinsing liquid from the substrate, is preferable. Further, it is preferable that a heating step (Post Bake) is included after the rinsing step. The residual developer and the rinsing liquid between and inside the patterns are removed by the baking. The heating step after the rinsing step is carried out at typically 40° C. to 160° C., and preferably at 70° C. to 95° C., and typically for 10 seconds to 3 minutes, and preferably for 30 seconds to 90 seconds.

It is preferable that various materials (for example, a resist solvent, a developer, a rinsing liquid, a composition for forming an antireflection film, and a composition for forming a topcoat) used in the actinic ray-sensitive or radiation-sensitive resin composition of the present invention and the pattern forming method of the present invention do not include impurities such as metals. The content of the impurities included in these materials is preferably 1 ppm or less, more preferably 100 ppt or less, and still more preferably 10 ppt or less, but the material not having substantially metal components (within a detection limit of a determination device or less) is particularly preferable.

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. As the filter, a filter which had been washed with an organic solvent in advance may be used. In the step of filtration using a filter, plural kinds of filters may be connected in series or in parallel, and used. In a case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method involving selecting raw materials having a small content of metals as raw materials constituting various materials, a method involving subjecting raw materials constituting various materials to filtration using a filter, and a method involving performing distillation under the condition with contamination being suppressed to the largest degree by, for example, lining the inside of a device with TEFLON (registered trademark). The preferred conditions for filtration using a filter, which is carried out for raw materials constituting various materials, are the same as described above.

In addition to filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

A method for improving the surface roughness of a pattern may be applied to the pattern formed by the pattern forming method of the present invention. Examples of the method for improving the surface roughness of a pattern include the method of treating a resist pattern by a plasma of a hydrogen-containing gas disclosed in WO2014/002808. In addition, known methods as described in JP2004-235468A, US2010/0020297A, JP2009-19969A, and Proc. of SPIE Vol. 8328 83280N-1 “EUV Resist Curing Technique for LWR Reduction and Etch Selectivity Enhancement” may be applied.

The pattern forming method of the present invention can be used for a guide pattern formation in a directed self-assembly (DSA) (see, for example, ACS Nano Vol. 4 No. 8 Pages 4815-4823).

In addition, a resist pattern formed by the method can be used as a core material (core) of the spacer process disclosed in JP1991-270227A (JP-H03-270227A) and JP2013-164509A.

In addition, the present invention further relates to a method for manufacturing an electronic device, including the pattern forming method of the present invention as described above. An electronic device manufactured by the method for manufacturing an electronic device of the present invention is suitably mounted on electric or electronic equipment (for example, home electronics, OA-related equipment, media-related equipment, optical equipment, and telecommunication equipment).

### EXAMPLES

Hereinafter, the present invention will be described with reference to Examples, but the present invention is not limited thereto.

### Synthesis Example 1: Synthesis of Resin B-1

55.6 parts by mass of cyclohexanone was heated at 80° C. under a nitrogen stream. While stirring this liquid, a mixed solution of 3.15 parts by mass of a monomer represented by Structural Formula M-1, 17.0 parts by mass of a monomer represented by Structural Formula M-2, 32.8 parts by mass of a monomer represented by Structural Formula M-3, 103.3 parts by mass of cyclohexanone, and 2.30 parts by mass of dimethyl 2,2′-azobisisobutyrate [V-601, manufactured by Wako Pure Chemical Industries, Ltd.] was added dropwise to the liquid for 6 hours. The solution after completion of the dropwise addition was further stirred at 80° C. for 2 hours to obtain a reaction solution. After the reaction solution was left to be cooled, 141.2 parts by mass of cyclohexanone was added thereto, and the reaction solution was reprecipitated with a large amount of methanol/water (mass ratio of 9:1). Then, the obtained solid was filtered and dried in vacuo to obtain 37.3 parts by mass of the following resin B-1.

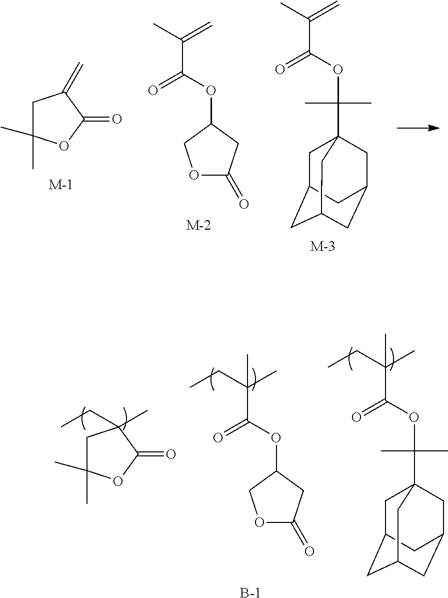

The weight-average molecular weight (Mw: in terms of polystyrene) of the obtained resin B-1, as determined by GPC (carrier: tetrahydrofuran (THF)), was as follows: Mw=9,500, and the dispersity was as follows: Mw/Mn=1.64. The compositional ratio (molar ratio; corresponding to the repeating units in order from the left side) measured by ¹³C-NMR (nuclear magnetic resonance) was 10/40/50.

In addition, the same operation as in Synthesis Example 1 was carried out to synthesize resins B-2 to B-12 described below.

<Preparation of Resist Composition>

The components shown in Table 1 were dissolved in the solvents shown in the same table at the blend ratio (unit:parts by mass) shown in the same table. The respective solutions were prepared so that their concentrations of the solid contents became 4% by mass.

In addition, the solutions were filtered through a polyethylene filter having a pore size of 0.05 μm to prepare resist compositions (resist compositions of Examples and Comparative Examples).

In addition, in Table 1, the numerical values in the parenthesis with regard to the solvents represent mass ratios.

<Evaluation>

(Evaluation of Depth of Focus (DOF))

A composition for forming an organic antireflection film, ARC29SR (manufactured by Nissan Chemical Industries, Ltd.), was applied onto a silicon wafer and baked at 205° C. for 60 seconds to form an antireflection film having a film thickness of 95 nm. A resist composition was applied onto the organic antireflection film, and baked (PB: Prebake) at 100° C. for 60 seconds, thereby forming a resist film having a film thickness of 100 nm.

The obtained resist film was exposed through a mask with pitches of 550 nm and a light shielding portion of 90 nm, using an ArF liquid immersion exposure device (XT1700i; manufactured by ASML, NA1.20, Annular, outer sigma 0.80, inner sigma 0.64). The exposed resist film was baked (Post Exposure Bake; PEB) at 100° C. for 60 seconds, and then developed using an organic developer (butyl acetate) to form a contact hole pattern having a hole diameter of 45 nm. In the formed contact hole pattern, exposure and development were carried out by changing the conditions of the exposure focus at an interval of 15 nm in the focus direction. The hole diameter (CD) of each of the obtained patterns was measured using a line-width length-measuring dimension scanning electron microscope SEM (S-9380; manufactured by Hitachi, Ltd.), and a variation in CD was observed. With regard to the maximum value in the observed CD, a focus variation width, at which 45 nm±10% was allowable, that is, a depth of focus (DOF) was calculated. The results are shown in Table 1. As the DOF value is higher, the CD variation for the focus deviation is smaller, and thus, the performance is excellent.

In addition, in Example 12, a topcoat layer having a thickness of 100 nm was provided on the resist film, using a topcoat composition including 2.5% by mass of a resin shown below, 0.5% by mass of an amine compound shown below, and 97% by mass of 4-methyl-2-pentanol solvent.

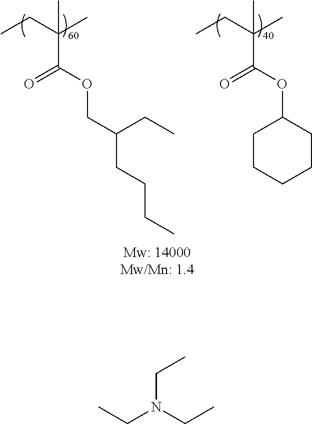

(Evaluation of Line Width Roughness (LWR))

A composition for forming an organic antireflection film, ARC29SR (manufactured by Nissan Chemical Industries, Ltd.), was applied onto a silicon wafer and baked at 205° C. for 60 seconds to form an organic antireflection film having a film thickness of 95 nm. The obtained resist composition was applied onto the organic antireflection film, and baked (PB: Prebake) at 100° C. for 60 seconds, thereby forming a resist film having a film thickness of 100 nm.

The obtained resist film was exposed through a 6% halftone mask with a 1:1 line-and-space pattern having a line width of 48 nm, using an ArF liquid immersion exposure machine (manufactured by ASML; XT1700i, NA1.20, C-Quad, outer sigma 0.900, inner sigma 0.812, and XY deflection). Ultrapure water was used as an immersion liquid. Thereafter, the exposed resist film was heated (PEB: Post Exposure Bake) at 100° C. for 60 seconds. Then, the resist film was developed by paddling it with butyl acetate for 30 seconds, and paddled and rinsed with a rinsing liquid [methylisobutyl carbinol (MIBC)] for 30 seconds. Then, the resist film was spun at a rotation speed of 4,000 rpm for 30 seconds to form a 1:1 line-and-space pattern having a line width of 48 nm. The formed line pattern (with a line width of 48 nm) at line/space=1/1 was observed using a line-width length-measuring scanning electron microscope SEM (S-9380, manufactured by Hitachi High-Technologies Corporation), and the line width was measured at 50 points within a range with an edge of 1 μm in the longitudinal direction of the line pattern. A standard deviation for the measurement differences was determined to calculate 3σ (unit: nm). The results (LWR) are shown in Table 1. A smaller value thereof indicates better performance.

In addition, in Example 12, in the same manner as in the case of the evaluation of DOF, a topcoat layer was provided.

TABLE 1

| | | | Acid | | Basic | | Hydrophobic | | | | |
|---|---|---|---|---|---|---|---|---|---|---|---|
| | Resin | | generator | | compound | | resin | | | | |
| | | parts by | | parts by | | parts by | | parts by | Solvent | DOF | LWR |
| | | mass | | mass | | mass | | mass | (mass ratio) | [nm] | [nm] |
| Example 1 | B-1 | 85.7 | A-1 | 11.0 | C-1 | 1.8 | 1b | 1.5 | A1/B1 (90/10) | 125 | 4.0 |
| Example 2 | B-2 | 84.8 | A-2 | 12.0 | C-2 | 2.5 | 2b | 0.7 | A1/B1 (90/10) | 105 | 4.5 |
| Example 3 | B-3 | 88.1 | A-3 | 9.5 | C-3 | 1.4 | 3b | 1.0 | A1/A2 (70/30) | 105 | 4.6 |
| Example 4 | B-4 | 86.1 | A-4 | 11.0 | C-4 | 1.2 | 4b | 1.7 | A1/B1 (90/10) | 125 | 4.0 |
| Example 5 | B-5 | 83.8 | A-5 | 14.0 | C-5 | 1.5 | 5b | 0.7 | A1/A2 (70/30) | 125 | 4.1 |
| Example 6 | B-6 | 87.0 | A-6 | 10.5 | C-6 | 1.3 | 1b | 1.2 | A1 | 125 | 3.9 |
| Example 7 | B-7 | 87.3 | A-7 | 11.0 | C-7 | 0.9 | 2b | 0.8 | A1/B2 (80/20) | 125 | 4.0 |
| Example 8 | B-8 | 85.5 | A-8 | 10.5 | C-8 | 1.5 | 3b | 2.5 | A1/B1 (90/10) | 105 | 4.6 |
| Example 9 | B-9 | 87.0 | A-9 | 9.0 | C-9 | 3.5 | 4b | 0.5 | A1/B1 (90/10) | 105 | 4.5 |
| Example 10 | B-10 | 87.0 | A-10 | 11.0 | C-1 | 1.5 | 5b | 0.5 | A1/B1 (90/10) | 125 | 4.0 |
| Example 11 | B-11 | 82.6 | A-2/A-5 | 13.0 | C-2 | 2.4 | 4b | 2.0 | A1/A2 (70/30) | 110 | 4.3 |
| | | | (2/8) | | | | | | | | |
| Example 12 | B-12/B-13 | 60.0/22.1 | A-3 | 14.0 | C-1/C-3 | 0.4/0.4 | 1b | 3.1 | A1/B1 (90/10) | 110 | 4.4 |
| Comparative | B-13 | 84.6 | A-1 | 12.0 | C-1 | 1.9 | 1b | 1.5 | A1 | 80 | 4.9 |
| Example 1 | | | | | | | | | | | |
| Comparative | B-14 | 86.5 | A-2 | 10.0 | C-2 | 2.8 | 2b | 0.7 | A1/A3 (95/5) | 65 | 4.9 |
| Example 2 | | | | | | | | | | | |
| Comparative | B-15 | 87.5 | A-3 | 9.5 | C-3 | 2.0 | 3b | 1.0 | A1/B1 (90/10) | 80 | 5.4 |
| Example 3 | | | | | | | | | | | |

In Table 1, the structures of the acid generators are as follows.

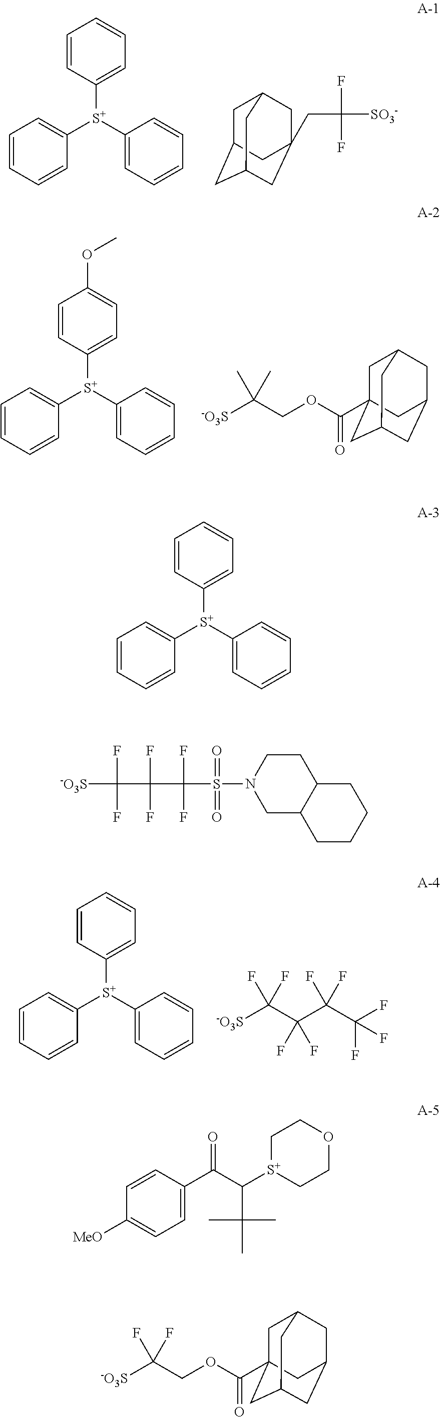

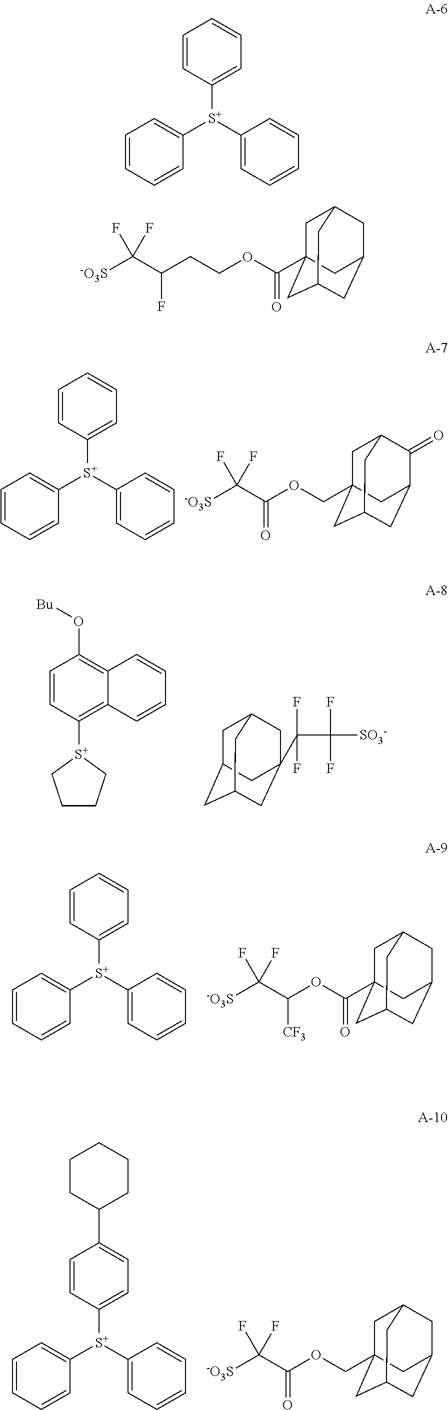

In Table 1, the structures of the resins used in Examples are as follows.

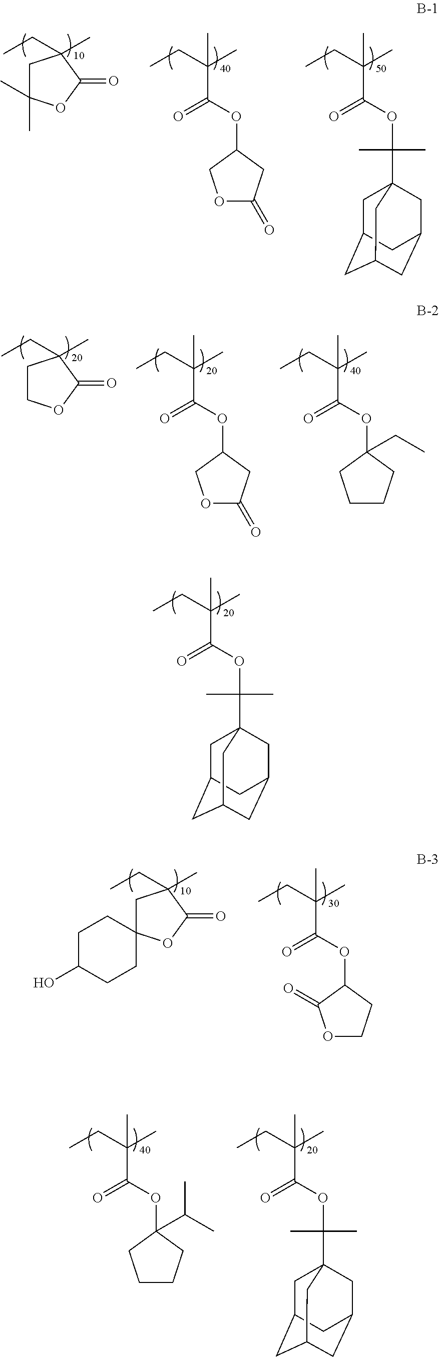

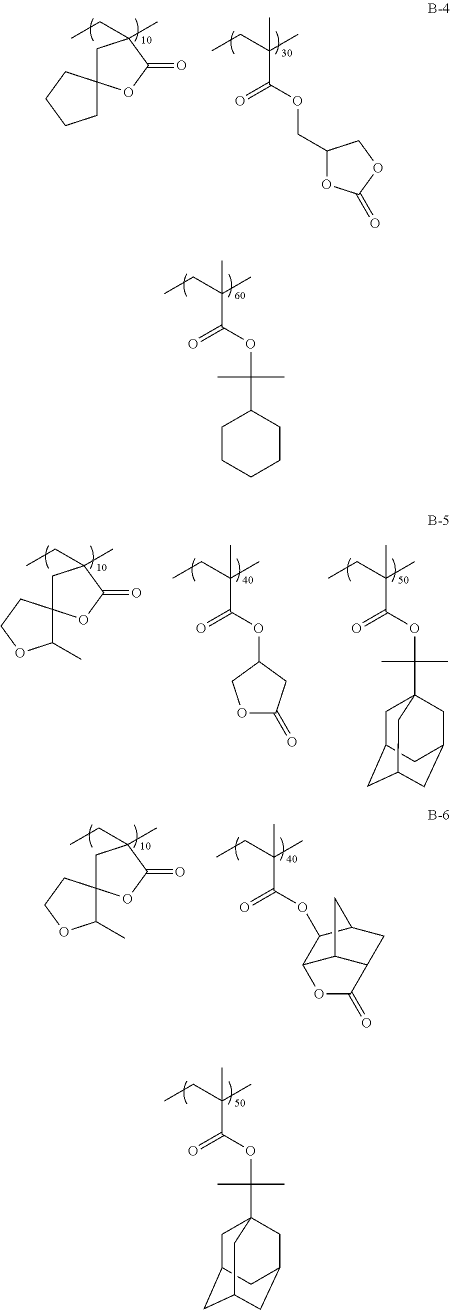

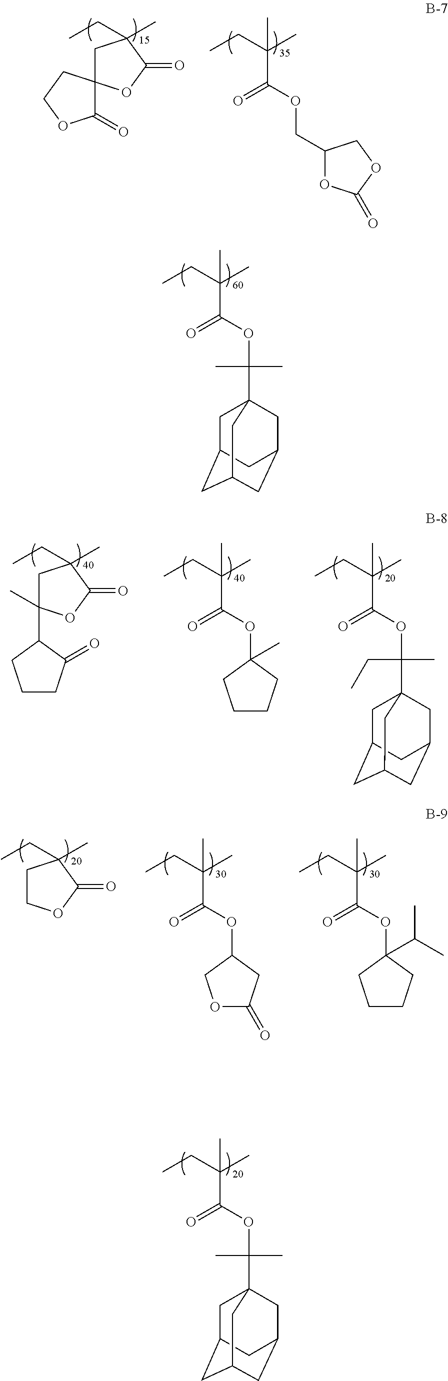

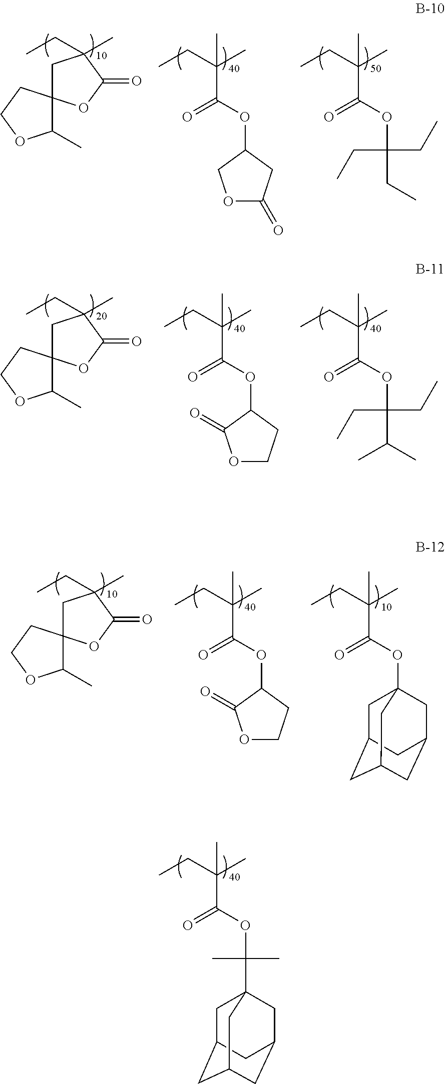

In Table 1, the structures of the resins used in Comparative Examples are as follows.

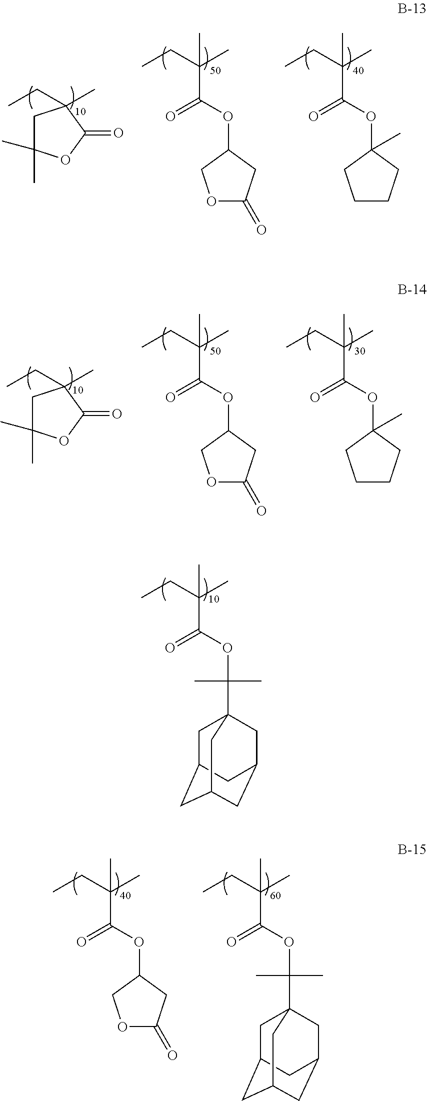

The compositional ratios of the repeating units are molar ratios. Further, the weight-average molecular weight (Mw) and the dispersity (Mw/Mn) are shown in Table 2. These were determined by the same method as for the above-mentioned resin B-1.

TABLE 2

| Resin | Mw | Mw/Mn |
|---|---|---|
| B-1 | 9,500 | 1.64 |
| B-2 | 10,300 | 1.48 |
| B-3 | 11,500 | 1.72 |
| B-4 | 9,000 | 1.65 |
| B-5 | 8,500 | 1.62 |
| B-6 | 14,000 | 1.66 |
| B-7 | 17,400 | 1.75 |
| B-8 | 12,500 | 1.59 |
| B-9 | 9,200 | 1.65 |
| B-10 | 8,300 | 1.58 |
| B-11 | 7,800 | 1.67 |
| B-12 | 10,000 | 1.75 |
| B-13 | 12,000 | 1.82 |
| B-14 | 9,400 | 1.63 |
| B-15 | 14,000 | 1.71 |

In Table 1, the structures of the basic compounds are as follows.

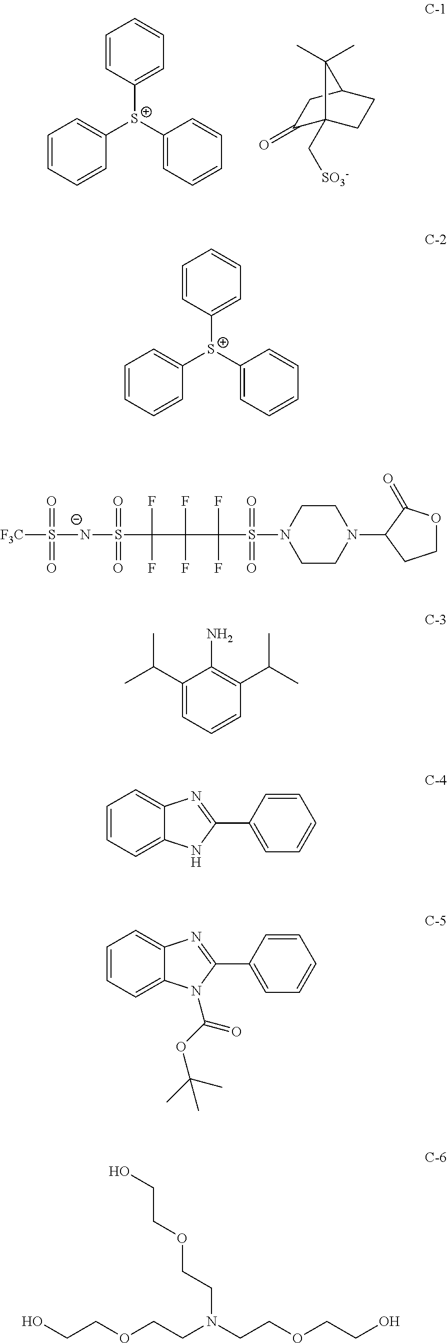

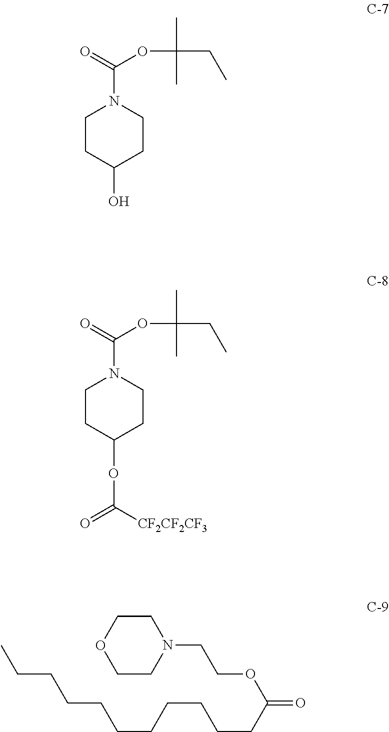

In Table 1, the structures of the hydrophobic resins are as follows.

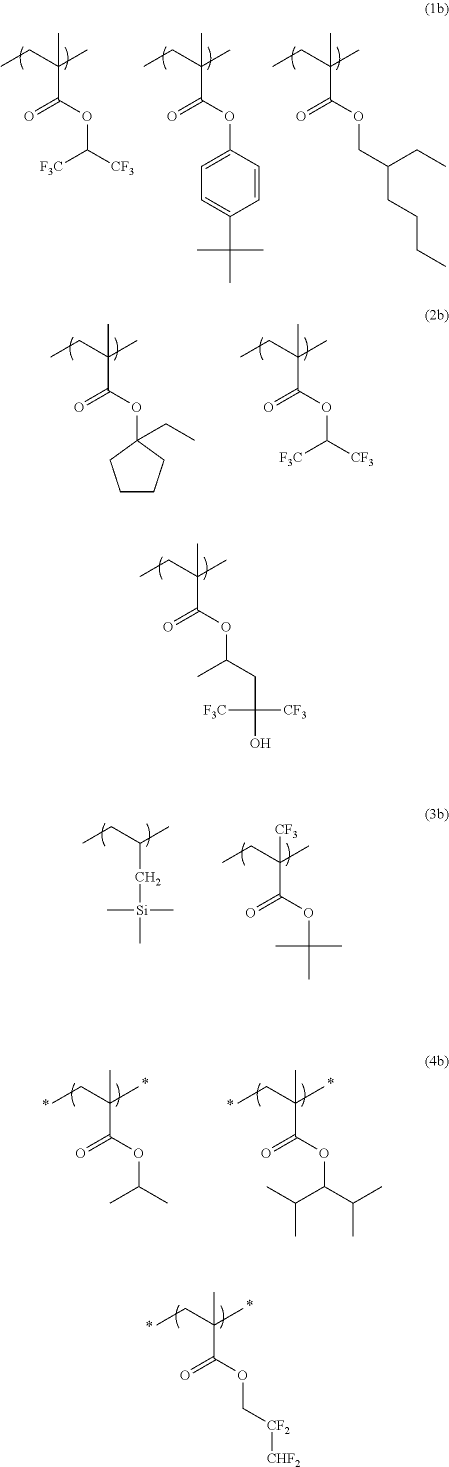

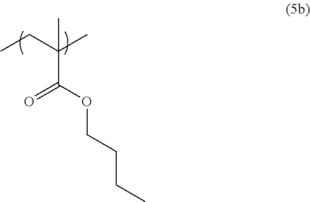

With respect to the respective hydrophobic resins, the compositional ratios (molar ratios; corresponding to the repeating units in order from the left side) of the respective repeating units, the weight-average molecular weight (Mw), and the dispersity (Mw/Mn) are shown in Table 3. These were determined by the same methods as for the above-mentioned resin B-1.

TABLE 3

| Resin | Compositional ratio (molar ratio) | | | Mw | Mw/Mn |
|---|---|---|---|---|---|
| (1b) | 50 | 45 | 5 | 7,000 | 1.30 |
| (2b) | 40 | 40 | 20 | 18,600 | 1.57 |
| (3b) | 50 | 50 | — | 25,400 | 1.63 |
| (4b) | 30 | 65 | 5 | 28,000 | 1.70 |
| (5b) | 100 | — | — | 12,500 | 1.65 |

In Table 3, the solvents are as follows.

A1: Propylene glycol monomethyl ether acetate (PGMEA)

A2: Cyclohexanone

A3: γ-Butyrolactone

B1: Propylene glycol monomethyl ether (PGME)

B2: Ethyl lactate

As seen from Table 1, in Examples 1 to 12 in which the resins B-1 to B-12 including the repeating unit Q1 and the repeating unit Q2, and having a content of the repeating units Q2 of 20% by mole or more was used, DOF was high and LWR was small, as compared with Comparative Examples 1 to 3.

In addition, Comparative Example 1 was an example in which the resin B-13 not including the repeating unit Q2 was used, Comparative Example 2 was an example in which the resin B-14 having a content of the repeating units Q2 of less than 20% by mole was used, and Comparative Example 3 was an example in which the resin B-15 not having the repeating unit Q1 was used.

When Examples 1 to 12 were compared with each other, in Examples 1, 4 to 7, and 10 to 12 in which the resins B-1, B-4 to B-7, and B-10 to B-12 having a content of the repeating units Q2 of 40% by mole or more were used, DOF and LWR were better.

In addition, in Examples 1, 4 to 7, and 10 in which the resin B-1, B-4 to B-7, and B-10 having a content of the repeating units Q2 of 50% by mole or more, DOF and LWR were better.

What is claimed is:

1. A pattern forming method comprising at least:
(i) forming an actinic ray-sensitive or radiation-sensitive resin composition film on a substrate, using an actinic ray-sensitive or radiation-sensitive resin composition;
(ii) irradiating the film with actinic rays or radiation; and
(iii) developing the film irradiated with actinic rays or radiation, using a developer containing an organic solvent,
wherein the actinic ray-sensitive or radiation-sensitive resin composition contains a resin P and a compound that generates an acid upon irradiation with actinic rays or radiation,
the resin P has a repeating unit Q1 represented by General Formula (q1) and a repeating unit Q2 represented by General Formula (q2), and
the content of the repeating unit Q2 with respect to all the repeating units of the resin P is 20% by mole or more, 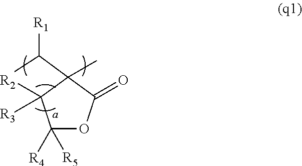
in General Formula (q1), R₁ represents a hydrogen atom or an organic group having 1 to 20 carbon atoms, R₂ to R₅ each independently represent a hydrogen atom, a fluorine atom, a hydroxy group, or an organic group having 1 to 20 carbon atoms, a represents an integer of 1 to 6, and R₂ and R₃, and R₄ and R₅ may be bonded to each other to form a ring structure having 3 to 10 ring members together with a carbon atom to which they are bonded; and 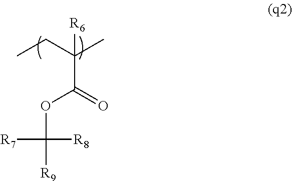
in General Formula (q2), R₆ represents a hydrogen atom or an organic group having 1 to 20 carbon atoms; R₇ and R₈ each represent a chain alkyl group which may include a branched structure having 1 to 10 carbon atoms; and R₉ represents an alkyl group which may include a branched structure having 1 to 10 carbon atoms or a monocyclic or polycyclic cycloalkyl group having 3 to 14 carbon atoms.

2. The pattern forming method according to claim 1, wherein in General Formula (q2), R₉ represents a polycyclic cycloalkyl group having 3 to 14 carbon atoms.

3. The pattern forming method according to claim 1, wherein the resin P further has a repeating unit having a lactone structure different from the repeating unit Q1.

4. The pattern forming method according to claim 2, wherein the resin P further has a repeating unit having a lactone structure different from the repeating unit Q1.

5. The pattern forming method according to according to claim 1,
wherein the content of the repeating unit Q2 with respect to all the repeating units of the resin P is 40% by mole or more.

6. The pattern forming method according to claim 2,
wherein the content of the repeating unit Q2 with respect to all the repeating units of the resin P is 40% by mole or more.

7. The pattern forming method according to claim 3,
wherein the content of the repeating unit Q2 with respect to all the repeating units of the resin P is 40% by mole or more.

8. The pattern forming method according to claim 5,
wherein the content of the repeating unit Q2 with respect to all the repeating units of the resin P is 50% by mole or more.

9. The pattern forming method according to claim 1,
wherein the resin P consists of the repeating unit Q1, the repeating unit Q2, and a repeating unit having a lactone structure different from the repeating unit Q1.

10. A method for manufacturing an electronic device, comprising:
the pattern forming method according to claim 1.

11. An actinic ray-sensitive or radiation-sensitive resin composition, comprising:
a resin P; and
a compound that generates an acid upon irradiation with actinic rays or radiation,
wherein the resin P has a repeating unit Q1 represented by General Formula (q1) and a repeating unit Q2 represented by General Formula (q2), and
the content of the repeating unit Q2 with respect to all the repeating units of the resin P is 20% by mole or more, 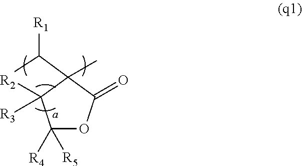
in General Formula (q1), R₁ represents a hydrogen atom or an organic group having 1 to 20 carbon atoms, R₂ to R₅ each independently represent a hydrogen atom, a fluorine atom, a hydroxy group, or an organic group having 1 to 20 carbon atoms, a represents an integer of 1 to 6, and R₂ and R₃, and R₄ and R₅ may be bonded to each other to form a ring structure having 3 to 10 ring members together with a carbon atom to which they are bonded; and 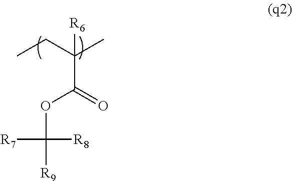
in General Formula (q2), R₆ represents a hydrogen atom or an organic group having 1 to 20 carbon atoms; R₇ and R₈ each represent a chain alkyl group which may include a branched structure having 1 to 10 carbon atoms; and R₉ represents an alkyl group which may include a branched structure having 1 to 10 carbon atoms or a monocyclic or polycyclic cycloalkyl group having 3 to 14 carbon atoms.

12. The actinic ray-sensitive or radiation-sensitive resin composition according to claim 11,
wherein in General Formula (q2), R₉ represents a polycyclic cycloalkyl group having 3 to 14 carbon atoms.

13. The actinic ray-sensitive or radiation-sensitive resin composition according to claim 11,
wherein the resin P further has a repeating unit having a lactone structure different from the repeating unit Q1.

14. The actinic ray-sensitive or radiation-sensitive resin composition according to claim 12,
wherein the resin P further has a repeating unit having a lactone structure different from the repeating unit Q1.

15. The actinic ray-sensitive or radiation-sensitive resin composition according to claim 11,
wherein the content of the repeating unit Q2 with respect to all the repeating units of the resin P is 40% by mole or more.

16. The actinic ray-sensitive or radiation-sensitive resin composition according to claim 12,
wherein the content of the repeating unit Q2 with respect to all the repeating units of the resin P is 40% by mole or more.

17. The actinic ray-sensitive or radiation-sensitive resin composition according to claim 13,
wherein the content of the repeating unit Q2 with respect to all the repeating units of the resin P is 40% by mole or more.

18. The actinic ray-sensitive or radiation-sensitive resin composition according to claim 15,
wherein the content of the repeating unit Q2 with respect to all the repeating units of the resin P is 50% by mole or more.

19. The actinic ray-sensitive or radiation-sensitive resin composition according to claim 11,
wherein the resin P consists of the repeating unit Q1, the repeating unit Q2, and a repeating unit having a lactone structure different from the repeating unit Q1.
